(19) United States
(12) Patent Application Publication
(10) Pub. No.: US 2023/0093115 A1
(43) Pub. Date: Mar. 23, 2023

(54) SPIKING NEURON CIRCUITS AND METHODS

(71) Applicant: Intel Corporation, Santa Clara, CA (US)

(72) Inventors: Assaf BEN-BASSAT, Haifa (IL); Elan BANIN, Raanana (IL); Alaa BEIDAS, Zahr el-Kanis (IL); Ofir DEGANI, Haifa (IL); Ashoke RAVI, Portland, OR (US)

(21) Appl. No.: 17/482,480

(22) Filed: Sep. 23, 2021

(51) Int. Cl. G06N 3/063; G06N 3/04; H03K 3/037

(52) U.S. Cl. CPC G06N 3/063; G06N 3/049; H03K 3/0372

(57) ABSTRACT

Spiking neuron circuits and methods are provided in this disclosure. A spiking neuron may include a triggerable and frequency-controllable oscillator that is configured to generate an oscillator signal. The spiking neuron may further include a spike signal detector that is configured to generate spike detection signals in response to detection of input spike signals. The spike signal detector may generate the spike detection signals based on the oscillator signal. The spiking neuron may further include a neuron structure that is configured to provide an output spike signal based on the spike detection signals and the oscillator signal.

### TECHNICAL FIELD

This disclosure generally relates to spiking neuron circuits and methods.

### BACKGROUND

Artificial neural networks (ANN) are computational models and systems that are inspired by the structure and functions of biological neural networks and they provide computation that is in a manner analogous to that of biological systems. Instead of traditional digital computation using zeros and ones, the artificial neural networks employ processing components that functionally resemble neurons of a biological brain. Artificial neural networks may include various types of electronic circuitry to physically realize the functions that are modeled on biological neurons as an alternative to traditional microprocessor implementation.

Spiking neural networks (SNN) include artificial neural networks that encode information using spikes via various methods such as rate encoding, or interval encoding. A spiking neural network (SNN) includes a network of spiking neurons, and each of the spiking neurons is configured to transmit a spike when the membrane potential of the spiking neuron reaches a predefined membrane potential threshold.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosure. In the following description, various aspects of the disclosure are described with reference to the following drawings, in which:

FIG. 1 shows an illustration of a plurality of neurons in a neural network;

FIG. 2 shows an illustration including three neurons in a neural network;

FIG. 3 shows schematically an example of an artificial neuron;

FIG. 4A, FIG. 4B, and FIG. 4C show illustrations of various electric signals related to a neuron circuit FIG. 5 shows schematically an example of a spiking neuron;

FIG. 6 shows schematically an example of a spike capturing element that may be coupled to an input of a spiking neuron;

FIG. 7 shows an example of a timing diagram illustrating various functions of a neuron circuit;

FIG. 8 shows an example of a timing diagram illustrating membrane potential accumulator and leakage accumulator of the neuron circuit;

FIG. 9 shows schematically an example of a computing system;

FIG. 10 shows schematically an example of a method;

### DESCRIPTION

The following detailed description refers to the accompanying drawings that show, by way of illustration, exemplary details and aspects in which aspects of the present disclosure may be practiced.

Traditional computing systems that are commonly used for general purposes depend on von Neumann architecture which includes a central processing unit that may include an arithmetic logic unit to perform mathematical operations and a control unit including registers, and a memory that may store data and instructions. The central processing unit and the memory are coupled to each other via a bus. Because the central processing unit is dependent on the data stored in the memory, the throughput of processing may be limited with the transfer rate of the bus between the central processing unit and the memory. When the central processing unit processes the data in the memory at a rate that is faster than the transfer rate of the bus, the central processing unit may simply wait for the data to arrive at its registers in an idle mode, decreasing the throughput of processing, and this concept may be referred as von Neumann bottleneck.

The above-mentioned limitation may be challenging in operations that may require the processing of data of great sizes, such as applications related to artificial intelligence, including deep learning and artificial neural networks. Alternatives architectures, such as graphics processing units that are specialized in various aspects including parallel processing in order to perform matrix calculations may provide a structure that may be suitable to support artificial neural networks, but there are still differences with respect to mechanisms of artificial neural networks, and such differences may result in inefficiencies and excessive power consumption.

Neuromorphic processors are designed in a manner that they are structured to mimic various aspects of biological brains. Neuromorphic processors may include a number of computing units that are referred to as artificial neurons that are connected to each other and they form a neural network in a manner that resembles biological neurons. The artificial neurons may communicate with each other using electrical signals that are formed as spike signals in a time-dependent manner in a spiking neural network as mentioned above.

The following detailed description refers to the accompanying drawings that show, by way of illustration, specific details and aspects in which the disclosure may be practiced.

The word “exemplary” is used herein to mean “serving as an example, instance, or illustration”. Any aspect or design described herein as “exemplary” is not necessarily to be construed as preferred or advantageous over other aspects or designs.

The words “plurality” and “multiple” in the description or the claims expressly refer to a quantity greater than one. The terms “group (of)”, “set [of]”, “collection (of)”, “series (of)”, “sequence (of)”, “grouping (of)”, etc., and the like in the description or in the claims refer to a quantity equal to or greater than one, i.e. one or more. Any term expressed in plural form that does not expressly state “plurality” or “multiple” likewise refers to a quantity equal to or greater than one. The terms “proper subset”, “reduced subset”, and “lesser subset” refer to a subset of a set that is not equal to the set, i.e. a subset of a set that contains fewer elements than the set.

As used herein, “memory” is understood as a non-transitory computer-readable medium in which data or information can be stored for retrieval. References to “memory” included herein may thus be understood as referring to volatile or non-volatile memory, including random access memory (RAM), read-only memory (ROM), flash memory, solid-state storage, magnetic tape, hard disk drive, optical drive, etc., or any combination thereof. Furthermore, registers, shift registers, processor registers, data buffers, etc., are also embraced herein by the term memory. A single component referred to as “memory” or “a memory” may be composed of more than one different type of memory, and thus may refer to a collective component including one or more types of memory. Any single memory component may be separated into multiple collectively equivalent memory components, and vice versa. Furthermore, while memory may be depicted as separate from one or more other components (such as in the drawings), memory may also be integrated with other components, such as on a common integrated chip or a controller with an embedded memory.

The term “software” refers to any type of executable instruction, including firmware.

As used herein, “artificial neuron” is understood as a processing element that is configured to perform a processing in a neural network. The artificial neuron may include various components, such as electronic circuits to provide operations mentioned in this disclosure. The electronic circuits may include analog circuits or digital circuits. The term “artificial neuron” and “neuron” are used in an interchangeable manner in this disclosure. The disclosure may include various examples that may specifically refer to neurons of a spiking neural network. However, it will be understood that these examples may also apply to other types of artificial neural networks. An artificial neuron may include a circuit.

As used herein, “spiking neuron” is understood as an artificial neuron suitable for a spiking neural network.

As used herein, “neural network” is understood as a network or circuit of neurons. The disclosure may include various examples that may specifically refer to spiking neural networks. However, it will be understood that these examples may also apply to other types of artificial neural networks.

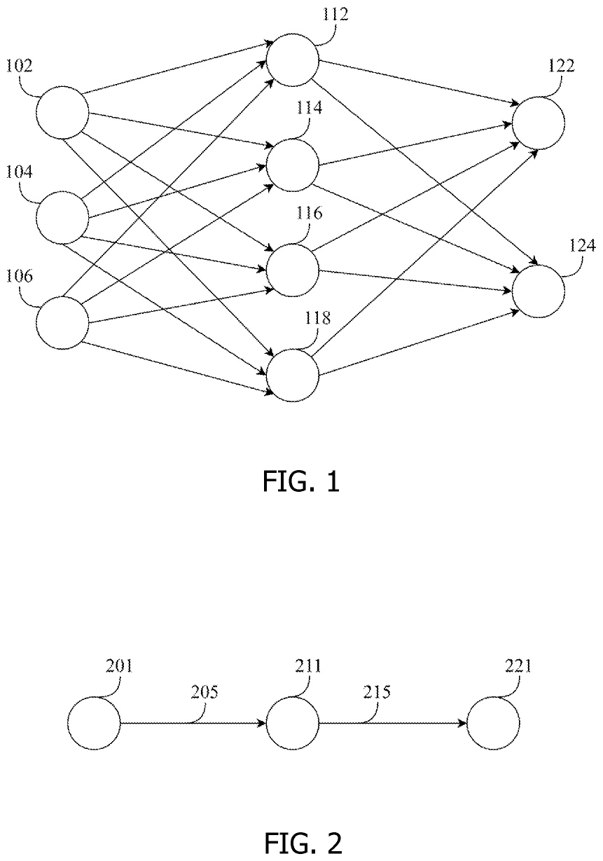

FIG. 1 shows an illustration of a plurality of neurons in a neural network. The neural network may include a spiking neural network. The neural network may include a plurality of neurons 102, 104, 106, 112, 114, 116, 118, 122, 124. The neural network may be structured in layers as in a first layer including input neurons 102, 104, 106, an intermediate layer including intermediate neurons 112, 114, 116, 118, and an output layer including intermediate neurons 122, 124.

The terminology used as “input”, “intermediate” and “output” are used only in order to refer to the corresponding neurons and/or layers that provide input and output to the neurons (or layer) 112, 114, 116, 118 illustrated in the middle layer. The input neurons 102, 104, 106 may be coupled to further neurons to receive input from the further neurons of another layer (e.g. a previous layer). The input neurons 102, 104, 106 may be neurons of an input layer of the neural network. Similarly, the output neurons 122, 124 may be coupled to further neurons to provide output to the further neurons of another layer (e.g. a following layer). The output neurons 122, 124 may be neurons of an output layer of the neural network. The elements that couple two neurons may also be referred as synapses.

The neural network may include further layers, and the layers (including the input layer, the output layer, and/or the middle layer) may include further neurons. The neurons may be grouped in a different manner, and/or one or more neurons of one of the layers may be configured to receive input only from a subset of a preceding layer. Similarly, one or more neurons of one of the layers may be configured to provide output only to a subset of a following layer.

In this example, each of the input neurons 102, 104, 106 are configured to couple each of the intermediate neurons 112, 114, 116, 118. Accordingly, each of the intermediate neurons 112, 114, 116, 118 may include 3 input fan-in connections. In other words, each of the intermediate neurons 112, 114, 116, 118 are configured to receive input from three neurons via synapses in-between. Each of the output neurons 122, 124 are configured to couple each of the intermediate neurons 112, 114, 116, 118. Accordingly, each of the output neurons 122, 124 may include 4 input fan-in connections. In other words, each of the output neurons 122, 124 are configured to receive input from four neurons via synapses in-between.

A first neuron that is immediately coupled to a second neuron via a synapse in a configuration that the first neuron provides an input to the second neuron may be referred to as a pre-synaptic neuron for the second neuron. A first neuron that is immediately coupled to a second neuron in a configuration that the first neuron receives an input from the second neuron via a synapse may be referred to as a post-synaptic neuron for the second neuron.

Accordingly, each of the input neurons 102, 104, 106 are pre-synaptic neurons for the intermediate neurons 112, 114, 116, 118. Each of the output neurons 122, 124 are post-synaptic neurons for the intermediate neurons 112, 114, 116, 118. The neural network may further include a plurality of pre-synaptic neurons that are coupled to the input neurons 102, 104, 106. The neural network may include a plurality of post-synaptic neurons that are coupled to the output neurons 122, 124.

Furthermore, each of the synapses (i.e. connections) that are configured to couple two of the neurons in the neural network may have a weight resembling synaptic weight which refers to the amount of influence that an input received from a pre-synaptic neuron has on a receiving neuron, similar to a biological neural network. The weight may be a scalar weight that may be adjustable. The neural network may be configured to adjust the weight of each of the synapses in order to resemble a learning mechanism, so that an input received from a first pre-synaptic neuron and an input received from a second pre-synaptic neuron may establish different influences on the receiving neuron, which the influence is adjusted through a learning process.

The weight of each of the synapses may be a scalar weight. The weight may include a weight of a positive value, which may be referred to as excitatory, resulting in an increase in the membrane potential of a receiving neuron. The weight may include a weight of a negative value, which may be referred to as inhibitory, resulting in a decrease in the membrane potential of a receiving neuron.

As indicated, each of the neurons 102, 104, 106, 112, 114, 116, 118, 122, 122 may further include a membrane potential that is specific to the neuron. The membrane potential may be a function that is dependent on time. The membrane potential of a receiving neuron may increase according to inputs received from pre-synaptic neurons. When the membrane potential of the receiving neuron reaches a certain level by the excitations from neurons that are pre-synaptic neurons to the receiving neuron, the receiving neuron fires (i.e. spikes) by providing input for one or more post-synaptic neurons.

FIG. 2 shows an illustration of three neurons in a neural network. The neural network as provided in FIG. 1 may include three neurons in a configuration that is depicted here (e.g. one of the input neurons, one of the intermediate neurons, and one of the output neurons). The illustration includes a first neuron 201, a second neuron 211, and a third neuron 221, a first synapse 205 that couples the first neuron 201 to the second neuron 211, and a second synapse 215 that couples the second neuron 211 to the third neuron 221.

When the first neuron 201 spikes, the second neuron 211 may receive the spike signal of the first neuron 201 as an input over the first synapse 205. The input spike signal which the second neuron 211 receives from the first neuron 201 may cause an adjustment to the membrane potential of the second neuron 211 according to a first weight that the first synapse 205 may provide. Accordingly, the membrane potential of the second neuron 211 may change over time based on input spike signals and the weight that the corresponding synapse provides.

Assuming that the second neuron 211 has not received any excitation for a period of time, the membrane potential of the second neuron 211 may be at a resting potential before the second neuron 211 receives the input spike signal. The neural network which includes the first neuron 201, the second neuron 211, and the third neuron 221 may further be configured in a manner that each of the neurons 201, 211, 221 may be configured to return to their membrane resting potential after a period of time that they receive an input spike signal. This behavior may be called “leaking” referring to the chemical leak of a biological neuron.

Accordingly, the second neuron 211 may be configured to decrease its membrane potential gradually over time. On the other hand, if the second neuron 211 receives a certain number of inputs that increase the membrane potential of the second neuron 211 over a membrane potential threshold, the second neuron 211 may output a spike signal (i.e. fires) to the third neuron 221 via the second synapse 215.

When the second neuron 211 spikes, the third neuron 221 may receive the spike signal of the second neuron 211 as an input over the second synapse 215. The input spike signal which the third neuron 221 receives from the second neuron 211 may cause an adjustment to the membrane potential of the third neuron 221 according to a second weight that the second synapse 215 may provide. Accordingly, the membrane potential of the third neuron 221 may change over time based on received input spike signals and the weight that the corresponding synapse provides. Similar to the mechanism of the second neuron 211, the third neuron 221 spike signals to further neurons when the membrane potential of the third neuron 221 is above the membrane potential threshold.

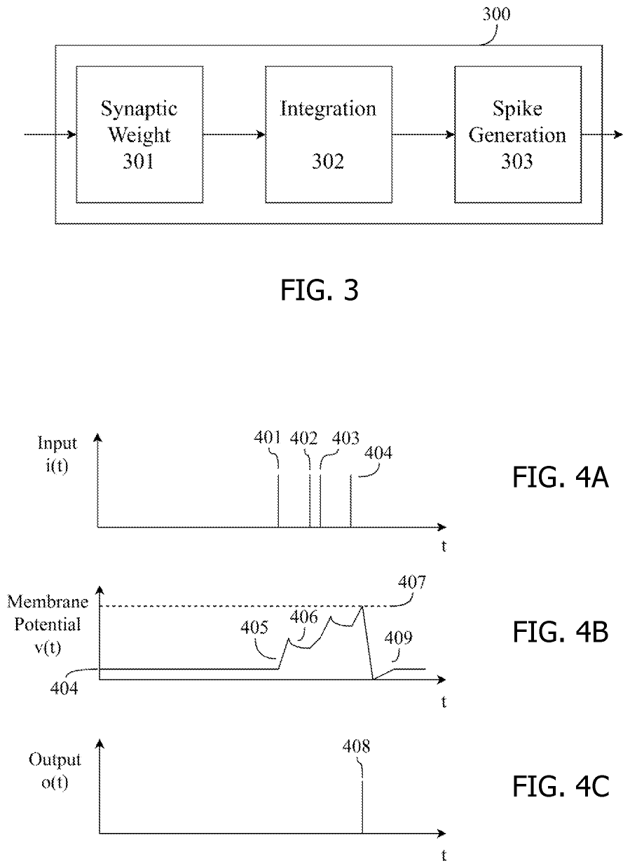

FIG. 3 shows schematically an example of an artificial neuron. The neuron 300 may be one of the neurons disclosed herein that may be modeled according to an integrate-and-fire model. The neuron 300 may include a synaptic weight block 301, an integration block 302, and a spike generation block 303 to provide various functions of an artificial neuron as provided in this disclosure. The neuron 300 may be based on, and/or may include, analog electrical circuits. The neuron 300 may be based on, and/or may include, digital electrical circuits to perform functions disclosed herein.

The synaptic weight block 301 may be coupled to a pre-synaptic neuron which is structurally and functionally similar to the neuron 300. The synaptic weight block 301 may be coupled to a plurality of pre-synaptic neurons. The synaptic weight block 301 may be configured to receive an input from one or more pre-synaptic neurons. The input that the neuron 300 receives from one or more pre-synaptic neurons may include a spike signal.

The synaptic weight block 301 may be configured to determine (and/or set, and/or define) how the input spike signal may influence the neuron 300, in particular, how the input spike signal may influence the integration block 302, which may be referred to as “weight” or “synaptic weight” in this disclosure. The weight that the synaptic weight block 301 determines may include a weight of positive value (excitatory). The weight that the synaptic weight block 301 determines may include a weight of negative value (inhibitory). The synaptic weight block 301 may apply the weight for the input spike signal.

The configuration of the synaptic weight block 301 may depend on the configuration of the integration block 302. As it is also indicated with respect to the integration block 302, the weights provided by the synaptic weight block 301 may indicate to the integration block 302 an amount of the adjustment that the integration block 302 may make to the value with respect to a predefined metric. The synaptic weight block 301 may determine the weight for the input spike signal and provide an indication related to the determined weight to the integration block 302, which the integration block 302 may use for the operation of the integration block 302. Furthermore, the synaptic weight block 301 may provide an indication of a presence of an input spike signal to the integration block 302. For example, the synaptic weight block 301 may provide an output signal to the integration block 302 based on the received input spike signal and the determined weight. The synaptic weight block 301 may be configured to provide the output signal to the integration block 302 when the synaptic weight block 301 receives an input spike signal, and accordingly, the integration block 302 may be configured to receive the indication of a received input spike signal and a determined weight for the received input spike signal.

The synaptic weight block 301 may determine the weight for the input spike signal and adjust at least one feature related to the input spike signal based on the determined weight and provide an electrical signal including the adjusted input spike signal to the integration block 302. The synaptic weight block 301 may provide an excitation to the integration block 302 with respect to the received input spike signal based on the determined weight in a manner in which the integration block 302 may determine the weight which the synaptic weight block 301 has set based on the excitation that the synaptic weight block 301 provides to the integration block 302. The synaptic weight block 301 may provide information indicating the determined weight to the integration block 302.

The synaptic weight block 301 may provide an indication related to the determined weight and/or a presence of an input spike signal a combination of various functions including the functions mentioned here. For example, the synaptic weight block 301 may include a pulse generator that is configured to generate one or more pulses based on a received input and a determined weight. The synaptic weight block 301 may provide the generated one or more pulses to the integration block 302. The generated one or more pulses may indicate a scalar determined weight. The synaptic weight block 301 may further provide information indicating whether the generated one or more pulses provided to the integration block 302 are of an excitatory nature or an inhibitory nature.

The synaptic weight block 301 may include, or may be coupled to, a memory configured to store information indicating a weight. Accordingly, the synaptic weight block 301 may determine the weight based on the information stored in the memory. Furthermore, the synaptic weight block 301 may be configured to determine different weights for a plurality of inputs that the synaptic weight block 301 is configured to receive input spike signals.

In other words, the synaptic weight block 301 may be configured to determine a first weight for an input spike signal that the neuron 300 receives from a first pre-synaptic neuron and a second weight for an input spike signal that the neuron 300 receives from a second pre-synaptic neuron. For example, the synaptic weight block 301 may include a memory (e.g. registers) to store information indicating a weight for each of the plurality of inputs. The synaptic weight block 301 may be configured to provide an output signal to the integration block 302, which the output signal may indicate the determined (stored) weight of an input when the synaptic weight block 301 receives an input spike signal from that input.

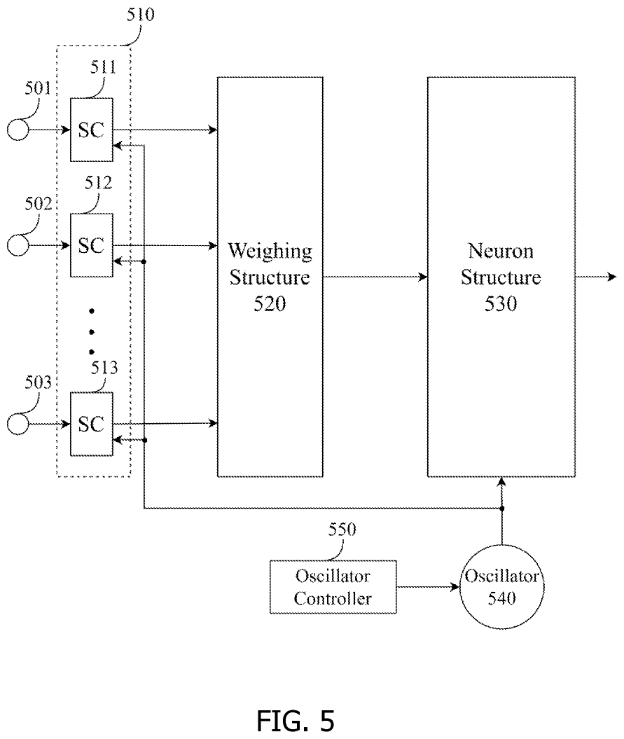

The integration block 302 may provide an integration function to the neuron 300, which may functionally include performing a uniting operation based on received input spike signals and the corresponding weights. There are various implementations to mimic the integration function provided by a biological neuron. The integration block 302 may perform certain operations based on a predefined metric to provide integration. As exemplarily shown in FIG. 4, the metric may be the voltage of an electrical signal, which may be referred as membrane potential similar to biological neurons. There are various types of metrics that the integration block 302 may use to provide an implementation to mimic the membrane potential of a biological neuron, such as information stored in a memory, using other attributes of electrical signals (e.g. current, frequency, phase, etc.), provided that the respective neuron is configured to provide an adjustment with respect to the metric based on the received input spike signals, and in particular with respect to their corresponding weights, and as a result, provide an output spike signal based on the adjustments with respect to the metric. The metric used by a neuron may be referred to as membrane potential sometimes in this disclosure.

When the neuron 300 has not received any input spike signal, or recently provided an output spike signal and has not received an input spike signal after the neuron 300 has provided the output spike signal, the value of the predefined metric tracked by the integration block 302 may be at a predefined resting value. The neuron 300 may provide an output spike signal in response to the value of the predefined metric reaching a predefined threshold. Received input spike signals may adjust the value of the predefined metric based on the corresponding weights for each of the received input spike signal. When the applied weight is an excitatory weight (i.e. when the input spike signal is excitatory), the integration block 302 may adjust the value of the predefined metric towards the predefined threshold according to the scale of the weight. When the applied weight is an inhibitory weight, the integration block 302 may adjust the value of the predefined metric towards the predefined resting value according to the scale of the weight. Furthermore, the integration block 302 may adjust the value of the predefined metric towards the predefined resting value according to a certain leakage rate. The integration block 302 may adjust the value of the predefined metric towards the predefined resting value according to the leakage rate in response to an oscillator signal (e.g. with each oscillation of the oscillator signal).

The integration block 302 may be configured to integrate based on an input received from the synaptic weight block 301. Accordingly, the integration block 302 may integrate for each of the input spike signals based on the weight that the synaptic weight block 301 indicates, and the integration block 302 may adjust the membrane potential based on the received input spike signal and the weight that the synaptic weight block 301 applies.

The integration block 302 may include a membrane potential storage that is configured to store the membrane potential and a membrane potential adjuster that is configured to adjust the membrane potential. The membrane potential storage and the membrane potential adjuster may include analog electrical circuits in a manner that is similar to a control of an electrical potential over electrical components, such as one or more transistors. The integration block 302 may include digital electrical circuits that are configured to store and adjust the membrane potential of the neuron 300 based on received input spike signals and the corresponding weights for each of the received input spike signals (e.g. an input received from the synaptic weight block 301).

The neuron 300 may have a membrane potential at a value of a resting membrane potential. The resting membrane potential may be zero, or a predefined value of a membrane potential. The resting membrane potential may be the membrane potential of the neuron 300 when the neuron 300 does not receive an input spike signal for a period of time. Based on an input which the integration block 302 may receive from the synaptic weight block 301 indicating at least a presence of an input spike signal, the integration block 302 may enter into another operation mode and adjust the membrane potential based on the input spike signal and the weight for the input spike signal. The integration block 302 may adjust (increase or decrease) the membrane potential with each input spike signal received over time based on their corresponding weights with respect to the inputs which the synaptic weight block 301 receives the input spike signals.

The integration block 302 may include a combiner (e.g. an adder) in order to combine the inputs received from the synaptic weight block 301, such as when the synaptic weight block 301 receives input spike signals simultaneously or within a predefined period of time. The combiner may be configured to perform a sum operation for the determined weight for the inputs that the synaptic weight block 301 has received an input spike signal. Accordingly, the synaptic weight block 301 may be configured to provide the output signal by indicating a sum of the determined weights of the inputs which the synaptic weight block 301 has received an input spike signal.

For example, the integration block 302 may include a digital counter that is coupled to the synaptic weight block 301. The digital counter may be configured to store the number of times which the digital counter receives an input (e.g. a pulse) from the synaptic weight block 301. The digital counter may be configured to increase (or decrease) when the synaptic weight block 301 provides an output of pulses based on a determined weight.

The integration block 302 may include an accumulator (e.g. a membrane potential accumulator) that is configured to add information indicating the determined weight that the integration block 302 receives from the synaptic weight block 301 in an accumulating configuration. The accumulator of the integration block 302 may be configured to receive the information indicating the determined weight which the synaptic weight block 301 provides. The received information may indicate the determined weight of one or more inputs (input spike signals).

Furthermore, the integration block 302 may include a leakage circuit that is configured to provide leaking resembling a leakage of a biological neuron. Referring to a biological neuron, the leakage function may decrease the membrane potential of the biological neuron towards the resting membrane potential of the biological neuron through chemical leaking. Accordingly, when the neuron 300 does not receive enough input spike signals having synaptic weights that would provide an increment to the membrane potential of the neuron 300 more than the decrement that the leakage function provides, the membrane potential of the neuron 300 falls back to the resting membrane potential. Alternatively, when the neuron 300 receives enough input spike signals having synaptic weights that would provide an increment to the membrane potential of the neuron 300 more than the decrement that the leakage function provides, the membrane potential may reach the membrane potential threshold and the neuron 300 may fire, but the neuron 300 may fire with a delay that is introduced to the neuron 300 by the leakage function.

Therefore, the leakage circuit may provide a leakage function in a conceptual manner, and the structure that is going to provide the leakage function may vary. As explained above, when the applied weight is an excitatory weight (i.e. when the input spike signal is excitatory), the integration block 302 may adjust the value of the predefined metric towards the predefined threshold according to the scale of the weight. When the applied weight is an inhibitory weight, the integration block 302 may adjust the value of the predefined metric towards the predefined resting value according to the scale of the weight. The leakage circuit may adjust the value of the predefined metric towards the predefined resting value according to a certain leakage rate. The integration block 302 may adjust the value of the predefined metric towards the predefined resting value according to the leakage rate in response to an oscillator signal (e.g. with each oscillation of the oscillator signal).

The leaking function may be any type of function that may affect the neuron 300 in a manner to introduce a delay to a period of time which begins with the neuron 300 receiving a first input spike signal changing the membrane potential from the resting membrane potential and ends with the neuron 300 firing, or in a manner to bring the neuron 300 back to its initial state.

For example, each neuron may have a plurality of operation modes, including a first operation mode (e.g. an initial operation mode) in which the neuron 300 has not received any input spike signal for a period of time. In the first operation mode, the neuron 300 may have its membrane potential at the resting membrane potential, as indicated above.

When the neuron 300 receives an input spike signal at an instance of time, the neuron 300 may start operating in a second operation mode in which the membrane potential of the neuron 300 changes from the resting membrane potential, or from the membrane potential of at the time instance if this is not the first spike signal that neuron 300 received for a period of time, towards the membrane potential threshold on which the neuron 300 will fire, and return to the first operation mode. Alternatively, if the neuron 300 does not receive enough input spike signals for a period of time the leakage function may bring the neuron 300 back to the first operation mode. Accordingly, the leakage function may include methods to bring the neuron 300 operating at the second operation mode back to the first operation mode, in particular, when the neuron 300 does not receive an input spike signal.

The leakage circuit may be configured to adjust the membrane potential that the integration block 302 stores in a manner to decrease the membrane potential over time. The leakage circuit may be configured to adjust the membrane potential when there is no input spike signal. The leakage circuit may be configured to adjust the membrane potential when the synaptic weight block 301 does not receive an input spike signal. The leakage circuit may be configured to adjust the membrane potential when the synaptic weight block 301 indicates to the integration block 302 that there is no spike signal. The synaptic weight block 301 may indicate that the synaptic weight block 301 does not receive an input spike signal by not providing an input to the integration block 302.

The leakage circuit may include an analog electrical circuit that is configured to generate a leakage current to decrease the membrane potential of the neuron 300. The leakage circuit may include a digital electrical circuit that is configured to adjust the membrane potential which the integration block 302 keeps. For example, the leakage circuit may be configured to provide an input to the counter which the integration block 302 keeps the membrane potential in a manner that the counter decreases the membrane potential with predefined decrements. The leakage circuit may be configured to provide the input to the counter periodically. The leakage circuit may be configured to provide input to the counter when there is no input spike signal.

The leakage circuit may be coupled to an oscillator that is configured to generate a signal with a predefined frequency. The oscillator may be coupled to the mechanism which the integration block 302 includes in order to keep the membrane potential in a manner that the generated oscillator signal provides a decrement to the membrane potential. For example, the accumulator, which the integration block 302 includes and which is configured to keep the membrane potential, may be configured to provide a predefined decrement to the accumulated membrane potential with each of the pulses of the generated oscillator signal.

Accordingly, the leakage circuit may adjust the membrane potential based on the oscillator signal. The leakage circuit may adjust the membrane potential based on the frequency of the oscillator signal. Accordingly, by adjusting the frequency of the oscillator signal, the leakage circuit may provide different adjustments to the membrane potential.

The spike generation block 303 may be configured to generate a spike signal to be transmitted to a post-synaptic neuron when the membrane potential of the neuron 300 reaches a membrane threshold of the neuron 300. The spike generation block 303 may include a comparator configured to compare the membrane potential of the neuron 300 and a predefined membrane potential threshold value. The spike generation block 303 may further include a pulse generator to generate a spike signal to be transmitted to the post-synaptic neuron. When the comparator determines that the membrane potential of the neuron 300 is over the predefined membrane potential threshold value, the comparator may trigger the pulse generator to generate a spike signal for the post-synaptic neuron.

In a second mode of operation, the neuron 300 may generate the spike signal with the spike generation block 303. Furthermore, when the membrane potential of the neuron 300 reaches the membrane threshold, or when the spike generation block 303 generates the spike signal, the spike generation block 303 resets the neuron 300 for another cycle of operation. The neuron 300 may reset the membrane potential by bringing the membrane potential to the resting membrane potential.

There are various methods with respect to a spiking neuron of a neural network, and in particular, with respect to the synaptic weight block 301, the integration block 302, and the spike generation block 303, and the disclosure above should be taken as exemplary and should be interpreted as functionally, as applicable, in order to realize a synaptic weight block 301 that is configured to weigh a received spike signal, an integration block 302 that is configured to keep track of membrane potential and adjust the membrane potential based on the weights of the received spike signals, and a spike generation block 303 that is configured to transmit a spike signal to a post-synaptic neuron when the membrane potential is over a predefined threshold.

FIG. 4A, FIG. 4B, and FIG. 4C show illustrations of various electric signals related to a neuron circuit. FIG. 4A shows input signals over time, which the neuron circuit may receive. FIG. 4B shows the membrane potential of the neuron circuit over time according to the received input signals in FIG. 4A. FIG. 4C shows the output signal of the neuron circuit over time according to the received input signals in FIG. 4A, and the membrane potential in FIG. 4B. The neuron circuit may be configured to operate according to a leaky integrate and fire model.

The neuron circuit may receive a first input spike signal 401, a second input spike signal 402, a third input spike signal 403, and a fourth input spike signal 404. The neuron circuit may receive each of the input spike signals 401, 402, 403, 404 from the same pre-synaptic neuron circuit, or from a plurality of synaptic circuits. For this example, the neuron circuit receives each of the input spike signals 401, 402, 403, 404 from a respective pre-synaptic neuron circuit. In other words, a first pre-synaptic neuron circuit provides the first input spike signal 401, a second pre-synaptic neuron circuit provides the second input spike signal 402, a third pre-synaptic neuron circuit provides the third input spike signal 403, and a fourth pre-synaptic neuron circuit provides the fourth input spike signal 404.

The neuron circuit may not have received any input spike signals before the first input spike signal 401, or the neuron circuit may not have received any input spike signals after the neuron circuit had fired an output spike signal and before receiving the first input spike signal 401. Accordingly, the membrane potential of the neuron circuit may be at a resting membrane potential 404 before receiving the first input spike signal 401.

The neuron circuit may receive the first input spike signal 401, and the membrane potential of the neuron circuit starts to increase 405 according to a first weight that the neuron circuit may determine for the first input spike signal 401. The neuron circuit may determine the first weight for the first input spike signal 401 according to the pre-synaptic neuron circuit which provides the first input spike signal 401 to the neuron circuit, which is the first pre-synaptic neuron circuit.

After the increase 405 of the membrane potential of the neuron circuit for the first input spike signal 401 according to the first weight, a leakage function (e.g. a leakage circuit) may introduce a decrement 406 on the membrane potential over time. The leakage function may be configured to adjust the membrane potential of the neuron circuit in order to bring the membrane potential to the resting membrane potential. The leakage function may be configured to operate when there is no input spike signal, which is depicted for a period of time between the first input spike signal 401 and the second input spike signal 402.

The neuron circuit may receive the second input spike signal 402, and the membrane potential of the neuron circuit may increase according to a second weight that the neuron circuit may determine for the second input spike signal 402. The neuron circuit may determine the second weight for the second input spike signal 402 according to the second pre-synaptic neuron circuit. The neuron circuit may receive the third input spike signal 403, and the membrane potential of the neuron circuit may increase according to a third weight that the neuron circuit may determine for the third input spike signal 403 in a similar manner as disclosed herein. As depicted here, since there is no input spike signal for a period of time between the third input spike signal 403 and the fourth input spike signal 404, the leakage function may provide another adjustment to the membrane potential over time.

The neuron circuit may receive the fourth input spike signal 404, and the membrane potential of the neuron circuit may increase according to a fourth weight. The membrane potential may reach a predefined membrane potential threshold 407. When the membrane potential reaches the predefined membrane potential threshold 407, the neuron circuit may output an output spike signal 408. The neuron circuit may be coupled to a plurality of post-synaptic neuron circuits to provide the output spike signal 408 to the plurality of post-synaptic neuron circuits.

Furthermore, the neuron circuit may enter into an operation mode in which the neuron circuit may reset its parameters to the initial mode of operation where the membrane potential is at the resting membrane potential 404. This period of time for reset may be referred to as the refractory period 409 of the neuron circuit. After the refractory period 409, the neuron circuit may have a membrane potential at the resting membrane potential 404, and the neuron circuit may be ready for another cycle of operation as disclosed herein.

FIG. 5 shows schematically an example of a spiking neuron. The spiking neuron may be an example of an artificial neuron as provided with respect to FIG. 3. The spiking neuron may include a plurality of inputs 501, 502, 503. The plurality of inputs 501, 502, 503 may receive input spike signals. The plurality of inputs 501, 502, 503 may receive input spike signals from a plurality of pre-synaptic neurons. Although it is depicted in the drawing that the spiking neuron includes three inputs 501, 502, 503 the spiking neuron may include more than (or less than) three inputs according to the fan-in input connection configuration of the spiking neuron.

The spiking neuron may further include a spike signal detector 510. The spike signal detector may be coupled to the plurality of inputs 501, 502, 503 of the spiking neuron. The spike signal detector 510 may detect input spike signals and provide indications of received spike signals for other components and/or circuits of the spiking neuron. Furthermore, the spike signal detector 510 may provide an indication of the input which received the input spike signal for other components and/or circuits of the spiking neuron.

The spike signal detector 510 may include a plurality of spike capturing elements 511, 512, 513. Each spike capturing element 511, 512, 513 may detect received input spike signals from the respective input 501, 502, 503 and may provide a received spike indication indicating a received input spike signal for the respective input 501, 502, 503 to other components and/or circuits of the spiking neuron. The spike indication may include a spike detection signal.

At least one of the spike capturing elements 511, 512, 513 may include a first logic that may switch a state of operation from a first state to a second state in response to a detection of a signal at the input which the respective spike capturing element 511, 512, 513 is coupled to. The first logic may switch the state of operation in response to the signal level of the input being above a predefined threshold (e.g. level-triggered) or in response to a transition of the signal level of the input (e.g. edge-triggered). The first logic may provide an output to indicate the state of the operation of the first logic.

The first logic may be coupled to a second logic. The second logic may generate a spike detection signal based on the state of the first logic. The second logic may receive the output which the first logic provides and generate the spike detection signal when the output of the first logic indicates the second state. The second logic may further receive an oscillator signal in which the neuron structure of the spiking neuron operates and generates the spike detection signal based on the oscillator signal. The second logic may generate the spike detection signal based on the output of the first logic in response to the oscillator signal. The second logic may generate the spike detection signal in a synchronized configuration with the oscillator signal, in other words, the generated spike detection signal may be in synchronization with the oscillator signal. The spike detection signal may include a pulse signal having a duration of a period of the oscillator signal.

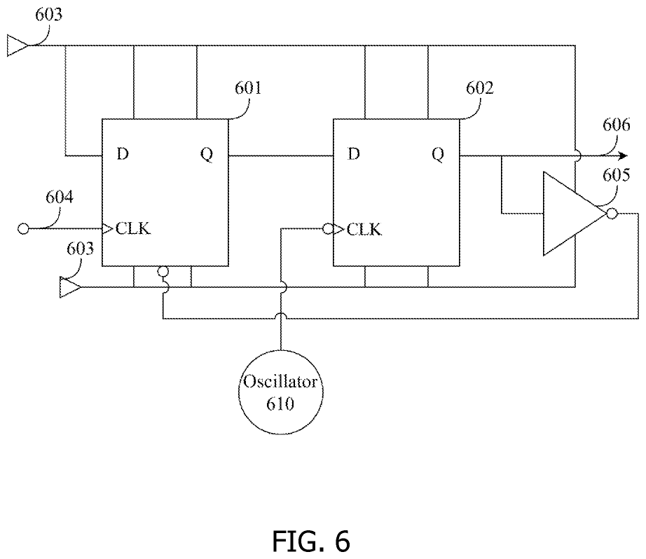

FIG. 6 shows schematically an example of a spike capturing element that may be coupled to an input of a spiking neuron. The spike capturing element may include a first flip-flop circuit 601 and a second flip-flop circuit coupled to each other. The flip-flop circuits 601, 602 may be coupled to each other in a master-slave configuration. The flip-flop circuits 601, 602 may receive supply voltage via a supply input 603 coupled to the flip-flop circuits 601, 602. The drawing is depicted to show D-type flip-flop circuits as examples, however, a spike capturing element may include any type of circuits that may provide the spike detection according to this disclosure.

The first flip-flop circuit 601 may be coupled to the input 604 of the spiking neuron via its clock signal input. The first flip-flop circuit 601 may be an edge-triggered flip-flop circuit. The first flip-flop circuit 601 may be a positive or negative edge-triggered flip-flop circuit. In this example, the first flip-flop circuit 601 is a positive edge-triggered flip-flop circuit.

When there is no input signal at the input 604, the first flip-flop circuit 601 may be at the first state, as the first flip-flop circuit 601 may constantly receive a high level signal input from its D-input, and output a low level signal indicating that the first flip-flop circuit 601 operates at the first state. When the first flip-flop circuit 601 receives an input spike signal, the first flip-flop circuit 601 may switch to the second state in response to the positive edge of the input spike signal and outputting a high level signal from its Q-output.

The Q-output of the first flip-flop circuit 601 may be coupled to the D-input of the second flip-flop circuit 602. The second flip-flop circuit 602 may further receive the oscillator signal which the neuron structure operates. The spiking neuron may include a triggerable and frequency-controllable oscillator 610 to provide the oscillator signal. The second flip-flop circuit 602 may include a D-type flip-flop circuit, in particular, an edge-triggered D-type flip-flop circuit, and particularly a negative edge-triggered D-type flip-flop circuit in this example. The D-input of the second flip-flop circuit 602 being at high level, the second flip-flop circuit 602 may change its state with the negative edge of the oscillator signal and may provide a high level output signal from its Q-output. The Q-output of the second flip-flop circuit 602 may be coupled to an inverter circuit 605 in order to reset the first flip-flop circuit 601 in response to the Q-output of the second flip-flop circuit 602 being at high level. In response to the reset of the first flip-flop circuit 601, the first flip-flop circuit 601 may asynchronously, and in response to the reset signal, may switch back to the first state and output a low level output signal from its Q-output, which may switch the second flip-flop circuit 602 back to its first state in response to a next negative edge of the oscillator signal.

Accordingly, the second flip-flop circuit 602 may output a pulse signal to the output of the signal detector. The pulse signal may be in synchronization with the oscillator signal, and the pulse signal may have a pulse duration of a period of the oscillator signal. Although the exemplary signal detector may include D-type flip-flop circuits, as provided above, any type of circuits can be used that may generate a spike detection signal in response to the input spike signal, which the spike detection signal is based on and in synchronization with the oscillator signal which the neuron structure operates.

The spike capturing elements 511, 512, 513 may be coupled to other components and/or circuits via different signal paths corresponding to each of the plurality of inputs 501, and each spike capturing element 511, 512, 513 may provide an output of the spike detection signal (e.g. a pulse signal) to another component and/or circuit from the respective signal paths corresponding to the respective input from the plurality of inputs 501, 502, 503.

The spiking neuron may further include a weighing structure 520 configured to apply a weight for each received input spike signal. The weighing structure 520 may implement functions of a synaptic weight block as disclosed according to FIG. 3, and analogous to the synaptic weight block, the weighing structure 520 may provide an indication with respect to how much should the received input spike signal affect the metric that the neuron structure uses for determining to generate an output spike signal for a post-synaptic synaptic neuron.

The weighing structure 520 may be configured to determine the weight to be applied for a received input spike signal. The weighing structure 520 may determine the weight to be applied for the received input spike signal based on the spike detection signal, in particular, based on which of the spike capturing elements 511, 512, 513 has provided the spike detection signal.

The weighing structure 520 may include, or may access via an interface, a memory to store weights (e.g. weight values) for received input spike signals. The memory may include information of a plurality of predefined weights for the plurality of inputs 501, 502, 503. The weighing structure 520 may receive one or more spike detection signals in response to a received input spike signal from one or more spike capturing elements 511, 512, 513 coupled to respective inputs 501, 502, 503, select the weight for one or more inputs that have received an input spike signal from the memory in response to the spike detection signal, for example, based on the respective spike capturing element 511, 512, 513 that provides the spike detection signal to the weighing structure 520, and provide an output indicating the selected weights. In other words, the weighing structure 520 may determine a weight for the input spike signal received by an input in response to the spike detection signal that spike capturing element coupled to the input provides.

The weighing structure 520 may provide an output including an indication of the determined weight for the received input spike signal. The weighing structure 520 may adjust at least one feature of the spike detection signal based on the weight and provide the output including an electrical signal including the adjusted spike detection signal. For example, the weighing structure 520 may adjust the amplitude of the spike detection signal based on the weight. The weighing structure 520 may adjust the duration of the spike detection signal based on the weight. The weighing structure 520 may provide a delay to the spike detection signal (e.g. relative to the oscillator signal that operates the neuron structure) based on the weight. The weighing structure 520 may provide information indicating the weight.

The weighing structure 520 may include a plurality of weight releasing elements coupled to the plurality of inputs 501, 502, 503 to receive the received spike input indication. Each weight releasing element may include a memory to store a weight value for the respective input. The memory may include a register configured to store preferably 4 to 8 bits for the weight value of the respective input, although the capacity may depend on the weight resolution configured for the neural network. Each weight releasing element may access a memory that stores the weight value for the weight releasing element. Each weight releasing element may provide an output indicating the weight for the respective input based on the spike detection signal received from the respective spike capturing element 511, 512, 513.

The spiking neuron may further include a neuron structure 530. The neuron structure 530 may be configured to implement certain functions of the integration block as described in FIG. 3 to adjust a value of a predefined metric based on received input spike signals, in particular, according to the weights defined for the received input spike signals, and output an output spike signal at an instance of time-based on the value of the predefined metric. For example, the neuron structure 530 may output the output spike signal in response to the value of the predefined metric being above (or below) a predefined threshold.

Furthermore, the neuron structure 530 may be configured to adjust the value of the predefined metric based on the oscillator signal. For example, the neuron structure 530 may adjust the value of the predefined metric based on the received input spike signals (e.g. spike detection signals) and based on the weights of the inputs that received the input spike signals to provide an integration function, while the neuron structure 530 may adjust the value of the predefined metric based on the oscillator signal to provide a leakage function.

When the spiking neuron has not received input spike signals, or recently provided an output spike signal and has not received an input spike signal after the spiking neuron has provided the output spike signal, the value of the predefined metric be at a predefined resting value. The spiking neuron may provide an output spike signal in response to the value of the predefined metric reaching a predefined threshold. Received input spike signals may adjust the value of the predefined metric based on the weight that the weighing structure 520 applies. When the applied weight is an excitatory weight, the neuron structure 530 may adjust the value of the predefined metric towards the predefined threshold according to the scale of the weight. When the applied weight is an inhibitory weight, the neuron structure 530 may adjust the value of the predefined metric towards the predefined resting value according to the scale of the weight. Furthermore, the neuron structure 530 may adjust the value of the predefined metric towards the predefined resting value according to a certain leakage rate. The neuron structure 530 may adjust the value of the predefined metric towards the predefined resting value according to the leakage rate in response to the oscillator signal (e.g. with each oscillation of the oscillator signal).

The neuron structure 530 may include an integration circuit to obtain an integration value with respect to the predetermined metric. The integration circuit may receive the output of the weighing structure 520 indicating the weights based on received input spike signals. The integration circuit may further perform a predefined mapping operation (e.g. a predefined function, a predefined mathematical operation) based on the received determined weights to obtain the integration value.

The weighing structure 520 may provide information indicating the weights for the inputs that may provide a spike detection signal to the neuron structure 530. The integration circuit may include an adder to perform a sum operation. The adder may perform the sum operation for the determined weights of each input that received an input spike signal. The adder may perform the sum operation for each of the determined weights that the adder received from the weighing structure 520 for the instance of time in which the weighing structure 520 provided the determined weights. The integration circuit may further include other circuits to perform the predefined mapping operation to obtain the integration value.

The integration circuit may further include a first accumulator which may be referred to as membrane potential accumulator in this disclosure. The membrane potential accumulator may receive the sum of the determined weights from the adder. The membrane potential accumulator includes a memory to store the integration value indicating the integration value at a first instance of time. The membrane potential accumulator may add the sum of the determined weights which the membrane potential accumulator may receive at a second instance of time to the integration value at the first instance of time to obtain the integration value at the second instance of time. The membrane potential accumulator may perform the accumulation in response to a spike detection signal.

The spiking neuron may further include a leakage circuit. The leakage circuit may be an example of the leakage circuit provided with respect to FIG. 3 to perform a leakage function for the spiking neuron. The leakage circuit may be configured to obtain a leakage value for the spiking neuron. The leakage value may indicate a leakage amount for the spiking neuron at an instance of time. The leakage circuit may obtain the leakage value based on the oscillator signal.

The spiking neuron may further include an oscillator, e.g. a triggerable oscillator 540 to generate the oscillator signal, and an oscillator controller 550. The oscillator controller 550 may activate or deactivate the triggerable oscillator 540. The oscillator controller 550 may activate or deactivate the triggerable oscillator 540 in response to a first spike detection signal which the oscillator controller 550 may receive when the integration value is at the predefined resting threshold. Furthermore, the oscillator controller 550 may activate or deactivate the triggerable oscillator 540 based on the leakage value and/or the integration value. The triggerable oscillator 540 may include a triggerable ring oscillator. The oscillator controller 550 may activate the triggerable oscillator 540 in response to a first spike detection signal. The oscillator controller 550 may deactivate the triggerable oscillator 540 based on the leakage value and the integration value.

The spiking neuron may have an initial operation mode as indicated above, in which the spiking neuron has not received any input spike, where the integration value is at a predefined resting integration value, and where the leakage value is at a predefined initial leakage amount. The triggerable oscillator 540 may be in a deactivated configuration at this stage. The deactivated configuration of the triggerable oscillator 540 may include that the triggerable oscillator 540 may not provide an output oscillator signal at all, or the triggerable oscillator 540 may not provide the oscillator signal to the neuron structure 530 or to the leakage circuit. As an alternative, the leakage circuit may not receive the oscillator signal in the deactivated configuration of the triggerable oscillator 540. Once the oscillator controller 550 activates the triggerable oscillator 540 in response to the spike detection signal, the triggerable oscillator 540 may be configured to provide the oscillator signal to the leakage circuit until the oscillator controller 550 deactivates the triggerable oscillator 540.

Based on the oscillator signal, the leakage circuit may obtain the leakage value indicating the leakage amount at an instance of time. The leakage circuit may be configured to adjust the leakage value at the instance of time with a predefined leakage rate value in response to the oscillator signal. The leakage circuit may be configured to adjust the leakage value with different leakage rates for a different instance of time to provide a non-linear effect. The leakage circuit may be configured to adjust the leakage value based on the integration value (e.g. as a mathematical function or a mapping operation including the integration value at an instance of time). The leakage circuit may include various elements that are configured to receive the oscillator signal as a clock signal and perform the adjustment for each oscillation of the oscillator signal.

For example, the leakage circuit may include a second accumulator, which may be referred to as a leakage accumulator in this disclosure. The leakage accumulator may be configured to adjust the leakage value in a similar manner to adjustment of the integration value by the membrane accumulator, but, in response to the oscillator signal. The leakage accumulator may accumulate the leakage value at a first instance of time by adding a predefined leakage rate value to the leakage value at a second instance of time (after the first instance of time) to obtain the leakage value at the second instance of time. A time period between the first instance of time and the second instance of time may be the period of the oscillator signal. Furthermore, the leakage circuit may perform further mapping operations to provide an adjustment (e.g. via bit-shifting, etc., a mapping operation including the integration value, based on a predefined transfer function/mapping operation of the integration value) based on the oscillator signal as provided in this disclosure to obtain the leakage value.

The triggerable oscillator 540 may provide the oscillator signal including a signal oscillating at a certain frequency that the oscillator controller 550 may control. The oscillator controller 550 may provide a control signal to the triggerable oscillator 540 to control the frequency of the oscillator signal which the triggerable oscillator 540 generates. The oscillator controller 550 may indicate a predefined frequency to the triggerable oscillator 550 while the triggerable oscillator 540 generates the oscillator signal.

The oscillator controller 550 may control the frequency of the oscillator signal based on the integration value. In order to obtain a desired leakage response for the spiking neuron, the oscillator controller 550 may control the triggerable oscillator 540 to adjust the frequency of the oscillator signal as the integration value increases (or decreases). The oscillator controller 550 may receive an indication of the integration value, or access the memory storing the integration value to adjust the frequency of the oscillator signal based on the integration value.

The oscillator controller 550 may control the frequency of the oscillator signal based on the leakage value. In order to obtain a desired leakage response for the spiking neuron, the oscillator controller 550 may control the triggerable oscillator 540 to adjust the frequency of the oscillator signal as the leakage value increases (or decreases). The oscillator controller 550 may receive an indication of the leakage value, or access the memory storing the leakage value to adjust the frequency of the oscillator signal based on the integration value.

The oscillator controller 550 may control the frequency of the oscillator signal based on the leakage value and the integration value (e.g. based on a difference of the integration value and the leakage value). In order to obtain a desired leakage response for the spiking neuron, the oscillator controller 550 may control the triggerable oscillator 540 to adjust the frequency of the oscillator signal based on the leakage value and the integration value. The oscillator controller 550 may receive an indication of the leakage value and the integration value, or access the memory (memories) storing the leakage value and the integration value, to adjust the frequency of the oscillator signal based on the integration value.

Furthermore, the oscillator controller 550 may receive an indication of a non-leaking operation. In response to a received indication of a non-leaking operation, the oscillator controller 550 may deactivate the triggerable oscillator 540. The oscillator controller 550 may deactivate the triggerable oscillator 540 in response to the indication of a non-leaking operation for a period of time. The oscillator controller 550 may deactivate the triggerable oscillator 540 in response to such indication until the spiking neuron fires. The oscillator controller 550 may deactivate the triggerable oscillator 540 in response to such indication until the oscillator controller 550 receives an indication of a leaking operation.

Based on the leakage value at an instance of time which the leakage circuit obtains and the integration value which the integration circuit obtains, the oscillator controller 550 may activate or deactivate the triggerable oscillator 540. The oscillator controller 550 may deactivate the triggerable oscillator 540 based on the leakage value and the integration value. The oscillator controller 550 may deactivate the triggerable oscillator 540 in case the leakage value is greater (or equal) than the integration value. Furthermore, the oscillator controller 550 may deactivate the triggerable oscillator 540 in case the integration value is above (or equal to) a predefined threshold (e.g. predefined metric threshold). The oscillator controller 550 may receive a signal from a determiner to activate or deactivate the triggerable oscillator 540.

The neuron structure 530 may further include a determiner. The determiner may perform various comparisons to determine various results. The determiner may determine activation or deactivation of the triggerable oscillator 540. The determiner may determine to deactivate the triggerable oscillator 540 based on the integration value and the leakage value at an instance of time. The determiner may include a comparator to compare the integration value and the leakage value. The determiner may determine to deactivate the triggerable oscillator 540 in case the leakage value is greater (or equal to) the integration value. The determiner may perform the determination with respect to the integration value and the leakage value based on the oscillator signal. Accordingly, the determiner may output a reset signal to provide the indication.

Furthermore, the determiner may determine to deactivate the triggerable oscillator based on the integration value and a predefined threshold value at an instance of time. The determiner may include a comparator to compare the integration value and the predefined threshold value. The determiner may determine to deactivate the triggerable oscillator 540 in case the integration value is greater than (or equal to) the predefined threshold value. The determiner may perform the determination with respect to the integration value and the predefined threshold value based on the trigger signal. In addition, the determiner may further determine to deactivate the triggerable oscillator 540 in case the integration value is less than the predefined resting membrane potential, for example, to disregard an inhibitory effect of a first input spike signal which the spiking neuron receives. Accordingly, the determiner may output a reset signal to provide the indication. Furthermore, the determiner may further output a firing indication to be provided to the spike generation circuit which generates an output spike in response to the firing indication.

In response to a reset signal, the spiking neuron may switch its operation mode to the initial operation mode. The integration circuit may reset the integration value to the predefined membrane resting potential value. The leakage circuit may reset the leakage value to the predefined initial leakage value. The weighing structure 520 may reset (or adjust based on a learning event) the weight values. The spiking neuron may include a delay circuit to provide a delay for a period of time between the respective determination of the determiner and the generation of the reset signal. Alternatively, a delay circuit may receive the reset signal to introduce a predefined delay for a refractory period.

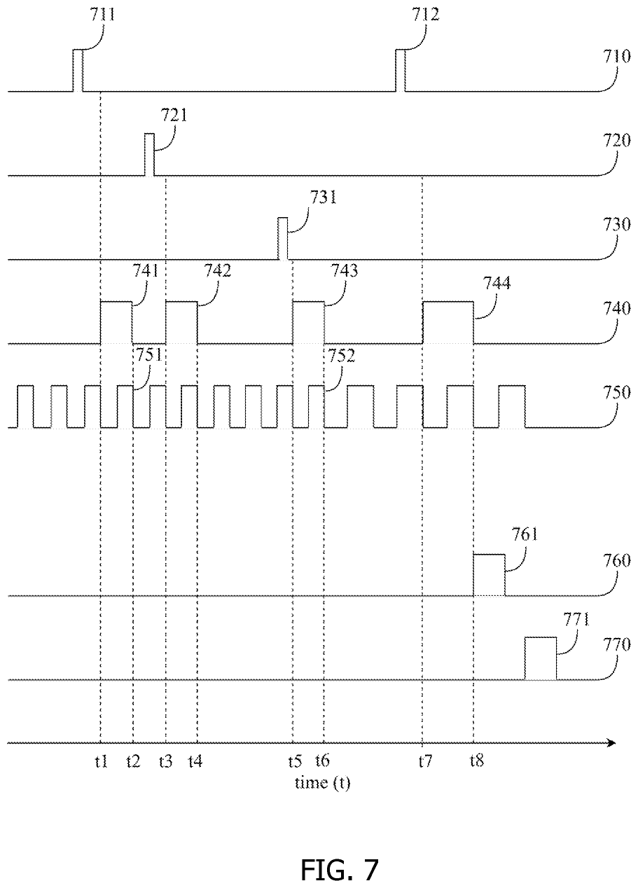

FIG. 7 shows an example of a timing diagram illustrating various functions of a neuron circuit. The neuron circuit may include the neuron circuit described in FIG. 5. The neuron circuit may include a plurality of inputs, and each of the inputs may be coupled to an output of a pre-synaptic neuron circuit. The plurality of inputs may include a first input, a second input, and a third input. Input signal characteristics (i.e. i(t), voltage over time) of the first input are provided as 710. Input signal characteristics of the second input are provided as 720. Input signal characteristics of the third signal are provided as 730.

The diagram further illustrates the spike detection signals which a spike signal detector generates in response to the detection of the respective input spike signals based on an oscillator signal which the neuron structure operates. The diagram further illustrates the oscillator signal 750 which a triggerable and frequency-controllable oscillator may generate. The diagram further illustrates the output signal characteristic of the neuron circuit 760, and the reset signal 770.

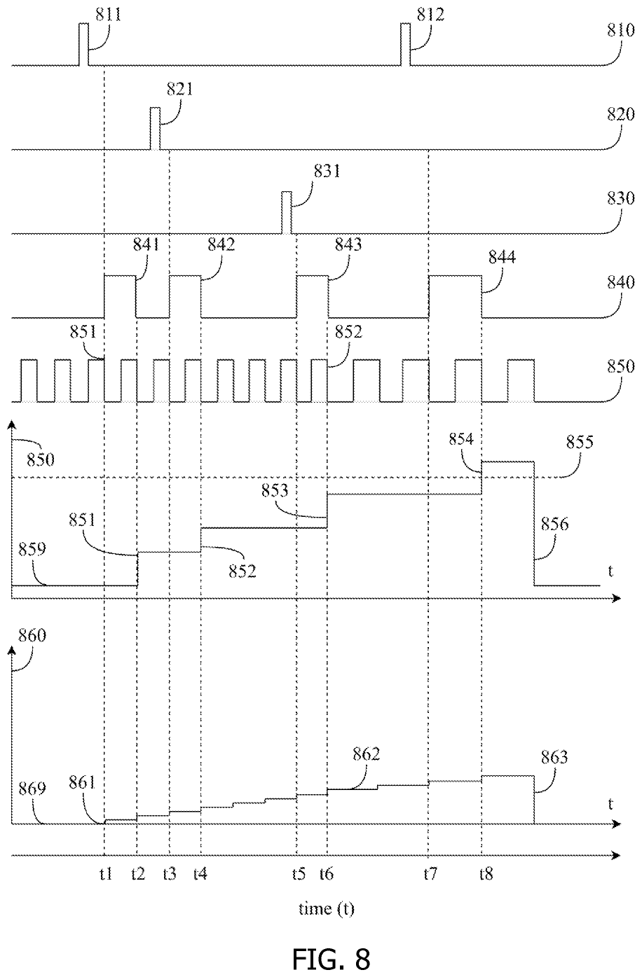

FIG. 8 shows an example of a timing diagram illustrating the integration value and the leakage value. A first accumulator (i.e. membrane potential accumulator) and a second accumulator (i.e. leakage accumulator) may store and accumulate the leakage value. The timing diagram of FIG. 8 illustrates certain characteristics that are the same as FIG. 7, such as the input signal characteristics of the first input 810, the input signal characteristics of the second input 820, the input signal characteristics of the third input 830, and the spike detection signals. Furthermore, the diagram includes a diagram showing the integration value 850 that may be stored in the first accumulator and the leakage value 860 that may be stored in the leakage accumulator. FIG. 7 and FIG. 8 are described collectively.

In these exemplary diagrams, the neuron circuit operates at a first operating mode before the neuron circuit receives a first spike signal 711, 811. At the first operation mode, there are no spike detection signals. The oscillator may operate in the first operating mode (e.g. a low power mode/turned off) as seen in 750, however, the neuron circuit may be configured such that the oscillator signal may not trigger any accumulation of the integration value or the leakage value in the first operation mode. The integration value is at a resting integration value 859, and the leakage value is zero 869. The integration value or the leakage value does not increase in the first operation mode.

The neuron circuit receives the first spike signal 711, 811. The spike signal detector may receive the first spike signal 711, 811 and, the spike signal detector may generate a first spike detection signal 741, 841 in response to the detection of the first spike signal 711, 811. The spike signal detector may further receive the oscillator signal and the spike signal detector may generate the first spike detection signal 741, 841 based on the oscillator signal at a first instance of time (t1). The spike signal detector may generate and/or output the first spike detection signal 741, 841 in response to the negative edge of the oscillator signal at the first instance of time (t1). The first spike detection signal 741, 841 may include a pulse signal that is in synchronization with the oscillator signal at the first instance of time (t1). The pulse signal may have a duration that may be equal to the period of the oscillator signal.

The neuron circuit may provide the first spike detection signal 741, 841 to various components of the neuron circuit to indicate a received input spike signal. The first spike detection signal 741, 841 may be the first signal that the neuron circuit may receive to switch the operation mode of the neuron circuit from the first operation mode to the second operation mode. Accordingly, the first spike detection signal 741, 841, may trigger the leakage accumulator to start accumulating the leakage value based on a predefined leakage rate and the oscillator signal. The oscillator signal may trigger the leakage accumulator with each oscillation to add the predefined leakage value to the leakage value of a previous instance of time to obtain the leakage value at the first instance of time (t1) (and also for further instance of time as seen in 860).

Although the example is provided with a fixed predefined leakage rate, the leakage accumulator may accumulate the leakage value based on the oscillator signal with a leakage rate based on the leakage value, or with a leakage rate based on the integration value, or with a leakage rate based on time. The neuron circuit may include a circuit or a component to perform a mapping operation (e.g. a bitwise operation, bit-shift operation) based on any one of the leakage value or the integration value to provide an output as the leakage rate. The neuron circuit may include a timer to adjust the leakage rate based on time.

Furthermore, the first spike detection signal 741, 841 may trigger a weighing structure to apply a weight for the first spike signal 711, 811. The weighing structure may apply the weight that was defined for the first input which received the first spike signal 711, 811. In this example, the weighing structure may provide a weight value for the first input that is stored in a memory to the membrane potential accumulator, and the membrane potential accumulator may perform the accumulation based on the received weight value.

The membrane potential accumulator may be configured so, such that the first spike detection signal 741, 841 may trigger the membrane potential accumulator to perform the accumulation with a negative transition of the first spike detection signal 741, 841 (from a signal of a high level to a low level) substantially at a second instance of time (t2). Accordingly, the membrane potential accumulator may add 851 the weight value of the first input to the membrane resting potential 859 (the integration value of an instance of time earlier than the second instance of time) increasing 851 the integration value of the neuron circuit to a first integration value at substantially the second instance of time (t2).

Furthermore, as provided in this disclosure the neuron circuit may perform further functions, including comparing the integration value 850 stored in the membrane potential accumulator (the first integration value) with a predefined membrane potential threshold 855, comparing the integration value 850 stored in the membrane potential accumulator (the first integration value) with the leakage value stored in the leakage accumulator, etc.

The neuron circuit may receive the second spike signal 721, 821. The spike signal detector may receive the second spike signal 721, 821 and, the spike signal detector may generate a second spike detection signal 742, 842 in response to the detection of the second spike signal 721, 821. The spike signal detector may further receive the oscillator signal and the spike signal detector may generate the second spike detection signal 742, 842 based on the oscillator signal at a third instance of time (t3). The spike signal detector may generate and/or output the second spike detection signal 742, 842 in response to the negative edge of the oscillator signal at the third instance of time (t3). The second spike detection signal 742, 842 may include a pulse signal that is in synchronization with the oscillator signal at the third instance of time (t3). The pulse signal may have a duration that may be equal to the period of the oscillator signal.

Furthermore, the second spike detection signal 742, 842 may trigger the weighing structure to apply a weight for the second spike signal 721, 821. The weighing structure may apply the weight that was defined for the second input which received the second spike signal 721, 821. In this example, the weighing structure may provide a weight value for the second input that is stored in a memory to the membrane potential accumulator, and the membrane potential accumulator may perform the accumulation based on the received weight value.

Similar to the operation with the first input spike signal 711, 811, the second spike detection signal 742, 842 may trigger the membrane potential accumulator to perform the accumulation with a negative transition of the second spike detection signal 742, 842 (from a signal of a high level to a low level) substantially at a fourth instance of time (t4). Accordingly, the membrane potential accumulator may add 852 the weight value of the second input to the first integration value increasing 852 the integration value of the neuron circuit to a second integration value at substantially the fourth instance of time (t4).

Furthermore, as provided in this disclosure the neuron circuit may perform further functions, including comparing the integration value 850 stored in the membrane potential accumulator (the second integration value) with the predefined membrane potential threshold 855, comparing the integration value 850 stored in the membrane potential accumulator (the second integration value) with the leakage value stored in the leakage accumulator, etc.

The neuron circuit may receive the third spike signal 731, 831. The spike signal detector may receive the third spike signal 731, 831 and, the spike signal detector may generate a third spike detection signal 743, 843 in response to the detection of the third spike signal 731, 831. The spike signal detector may further receive the oscillator signal and the spike signal detector may generate the third spike detection signal 743, 843 based on the oscillator signal at a fifth instance of time (t5). The spike signal detector may generate and/or output the third spike detection signal 743, 843 in response to the negative edge of the oscillator signal at the fifth instance of time (t5). The third spike detection signal 743, 843 may include a pulse signal that is in synchronization with the oscillator signal at the fifth instance of time (t5). The pulse signal may have a duration that may be equal to the period of the oscillator signal.

Furthermore, the third spike detection signal 743, 843 may trigger the weighing structure to apply a weight for the third spike signal 731, 831. The weighing structure may apply the weight that was defined for the third input which received the third spike signal 731, 831. In this example, the weighing structure may provide a weight value for the third input that is stored in a memory to the membrane potential accumulator, and the membrane potential accumulator may perform the accumulation based on the received weight value.

Similar to the operation with the first input spike signal 711, 811, the third spike detection signal 743, 843 may trigger the membrane potential accumulator to perform the accumulation with a negative transition of the third spike detection signal 743, 843 (from a signal of a high level to a low level) substantially at a sixth instance of time (t6). Accordingly, the membrane potential accumulator may add 853 the weight value of the third input to the second integration value increasing 853 the integration value of the neuron circuit to a third integration value at substantially the sixth instance of time (t6).

Furthermore, as provided in this disclosure the neuron circuit may perform further functions, including comparing the integration value 850 stored in the membrane potential accumulator (the third integration value) with the predefined membrane potential threshold 855, comparing the integration value 850 stored in the membrane potential accumulator (the third integration value) with the leakage value stored in the leakage accumulator, etc.

In this example, the oscillator controller may adjust the frequency of the oscillator signal at the sixth instance of time (t6). The oscillator controller may adjust the frequency of the oscillator signal based on a control signal received from a component and/or a circuit. The oscillator controller may adjust the frequency of the oscillator signal based on a received input spike signal. The oscillator controller may adjust the frequency of the oscillator signal based on at least one of the integration value, and/or the leakage value, and/or the predefined membrane potential threshold. The neuron circuit may include a timer, and the oscillator controller may adjust the frequency of the oscillator signal based on time information provided by the timer. For example, the oscillator controller may adjust the frequency of the oscillator signal when the timer indicates that a period of time has elapsed starting from the first input spike signal 711, 811. The oscillator controller may provide a control signal to the triggerable and the frequency-controllable oscillator to adjust the frequency of the oscillator. In this example, the oscillator controller decreased the frequency of the oscillator signal at the sixth instance of time (t6).

The adjustment of the oscillator signal may affect the leakage buildup. Since the oscillator controller has adjusted the oscillator signal to operate at a lower frequency, and the oscillator signal triggers the leakage accumulator to perform the accumulation, the leakage value may increase with a slower rate 862.

The neuron circuit may receive the fourth spike signal 712, 812. The spike signal detector may receive the fourth spike signal 712, 812 and, the spike signal detector may generate a fourth spike detection signal 744, 844 in response to the detection of the fourth spike signal 712, 812. The spike signal detector may further receive the oscillator signal and the spike signal detector may generate the fourth spike detection signal 744, 844 based on the oscillator signal at a seventh instance of time (t7). Since the frequency of the oscillator signal has decreased at the sixth instance of time (t6), it is noted that the spike signal detector may generate the fourth spike detection signal 744, 844 based on the oscillator signal which has a lower frequency than earlier instances of time.

The spike signal detector may generate and/or output the fourth spike detection signal 744, 844 in response to the negative edge of the oscillator signal at the seventh instance of time (t7). The fourth spike detection signal 744, 844 may include a pulse signal that is in synchronization with the oscillator signal at the seventh instance of time (t7). The pulse signal may have a duration that may be equal to the period of the oscillator signal. It is noted that since the frequency of the oscillator signal has changed, the pulse signal of the fourth spike detection signal 744, 844 may have more duration than the pulse signals of earlier instances of time.

Furthermore, the fourth spike detection signal 744, 844 may trigger the weighing structure to apply a weight for the fourth spike signal 712, 812. The weighing structure may apply the weight that was defined for the first input which received the fourth spike signal 712, 812. In this example, the weighing structure may provide the weight value for the first input that is stored in the memory to the membrane potential accumulator, and the membrane potential accumulator may perform the accumulation based on the received weight value.

Similar to the operation with the first input spike signal 711, 811, the fourth spike detection signal 744, 844 may trigger the membrane potential accumulator to perform the accumulation with a negative transition of the fourth spike detection signal 744, 844 (from a signal of a high level to a low level) substantially at an eighth instance of time (t68. Accordingly, the membrane potential accumulator may add 854 the weight value of the first input to the third integration value increasing 854 the integration value of the neuron circuit to a fourth integration value at substantially the eighth instance of time (t8).

Furthermore, as provided in this disclosure, the neuron circuit may perform further functions, including comparing the integration value 850 stored in the membrane potential accumulator (the fourth integration value) with the predefined membrane potential threshold 855. As depicted in the diagram with respect to the integration value 850, the fourth integration value stored in the accumulator is above the predefined membrane threshold 855.

The neuron circuit may include a logic to provide an indication that the integration value 850 is above the predefined membrane threshold 855 to a pulse generator to generate an output spike signal 761. In an alternative, the neuron circuit may compare a difference of the integration value and the leakage value with the predefined membrane threshold 855 to provide an indication to the pulse generator to generate an output spike signal 761. The indication may further include the reset signal 771. The neuron circuit may be configured to provide the reset signal to various components to change the operation of the neuron circuit (or various components) back to the first operation mode. Exemplarily, the neuron circuit may include a delay component to provide a predefined time delay to the reset signal to introduce a refractory period for the neuron circuit after the neuron circuit has provided the output spike signal, as shown in this example.

The neuron circuit may be configured to convey the reset signal to the oscillator controller, so that the oscillator controller may deactivate the oscillator. The neuron circuit may be configured to convey the reset signal to the membrane potential accumulator to reset the membrane potential accumulator (i.e. adjust the integration value 850 back 856 to the resting membrane potential 859). The neuron circuit may be configured to convey the reset signal to the leakage accumulator to reset the leakage accumulator (i.e. adjust the leakage value 860 back 863 to the initial leakage value 869 which is zero).

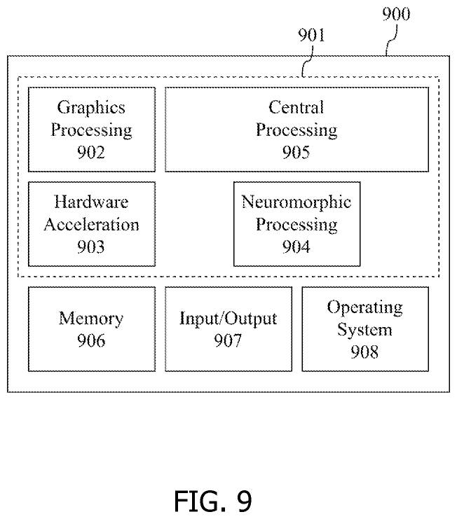

FIG. 9 shows schematically an example of a computing system. The computing system 900 may be implemented by another system or device, for example, a computer e.g. a desktop computer or a tablet computer, a mobile device, a mobile communication device e.g. a mobile terminal or a smartphone, a wearable device e.g. a smart watch or a smart googles, a device for a smart home (domotics), an internet of things (IoT) device, a vehicle computer e.g. an autonomous vehicle or an automated and/or assisted driving vehicle, an edge device, etc.

The computing system 900 may include components which may include hardware components and/or software components. The computing system may include one or more processors 901, e.g. a graphics processing unit 902, a hardware acceleration unit 903, a neuromorphic processing unit 904, and a central processing unit 905. The one or more processors 901 may be implemented in one processing unit, e.g. a system on chip (SOC), or a processor.

The graphics processing unit 902 may include a processing unit (or one or more processors) that is configured to process input data and alter data in a memory in a relatively efficient manner with algorithms and functions that are directed towards computer graphics and image processing. The graphics processing unit 902 may include a general-purpose graphics processing unit (GPGPU) which may be further configured to process input data that may be related to non-graphical operations as well.

The hardware acceleration unit 903 may include one or more processors that are configured to provide efficient processing that is directed to predefined tasks in a specialized manner. The hardware acceleration unit 903 may include certain functions that are directed to predefined tasks. The hardware acceleration unit 903 may include, for example, a field-programmable gate array (FPGA) directed to one or more tasks, one or more application-specific integrated circuits (ASIC), a deep learning processor (DLP), a deep learning accelerator, a neural processing unit, an artificial intelligence (AI) processor, a graphics processing unit, a vision processing unit, etc.

The neuromorphic processing unit 904 may include a plurality of neuron circuits as provided in this disclosure to form a neural network. The neural network may include a spiking neural network. The neuromorphic processing unit 904 may include a plurality of neuromorphic cores.

Each of the neuromorphic cores may include one or more neuron circuits. The neuromorphic cores may be coupled to each other in a network configuration such as a mesh configuration, a ring configuration, etc. The neuromorphic cores may be configured to transmit and receive spike signals to each other in the network configuration. Similar to the operation of the neurons as provided in this disclosure, a neuromorphic core may be configured to provide an output spike signal(s) for the neuron circuits which the neuromorphic core includes when the spike signals which the neuromorphic core receives from other neuromorphic cores accumulate for a period of time and reach to a neuromorphic core threshold.

The neuromorphic processing unit 904 may include one or more learning engines that are configured to provide a learning function. The one or more learning engines may be configured to adjust synaptic weight elements to provide the learning function based on iterations. A memory may include the synaptic weight elements for each of the neuron circuits, and a learning engine may be configured to adjust the synaptic weight elements of each of the neuron circuits stored in the memory. The one or more learning engines may be configured to adjust membrane thresholds of the neuron circuits to provide the learning function based on iterations. A memory may include the membrane potential threshold value for each of the neuron circuits, and a learning engine may be configured to adjust the membrane potential threshold value of each of the neuron circuits stored in the memory. The learning engine may be configured to provide an adjustment to a resting membrane potential of a neuron circuit, and/or an initial leakage value of a neuron circuit, and/or a leakage increment value of a neuron circuit with a similar operation in order to provide the learning function. The learning engines may be configured to provide an adjustment as exemplarily disclosed above, after observing outcomes for a period of time which may be referred to as “learning epoch” for the neuron circuits. Each of the plurality of neuromorphic cores may include a learning engine that is configured to provide the learning function for the neuron circuits which the respective neuromorphic core includes.

The neuromorphic processing unit 904 may include a memory (not shown) to provide storage with respect to various functions of the neuromorphic processing unit 904 (e.g. storing operating parameters of neuron circuits, such as synaptic weight elements, membrane thresholds, etc.). The neuromorphic processing unit 904 may be configured to perform in-memory processing. The neuromorphic processing unit 904 may be coupled to the memory 906 of the computing system 900. The neuromorphic processing unit 904 may include a controller that is configured to perform various functions to control the operation of the neuromorphic processing unit 904. The neuromorphic processing unit 904 may further be configured to receive control instructions from the central processing unit 905 or any one of the one or more processors 901 of the computing system 900. The neuromorphic processing unit 904 may include one or more routers to provide communication between the neuromorphic cores.

The computing system 900 may further include an input/output unit 907. The input/output unit 907 may include an interface to receive input data from an input component and/or device. The interface may be configured to provide output data to an output component and/or device. The input/output unit 907 may further include an output component and/or device, such as a display, and/or a touchscreen display, and/or a loudspeaker, and/or a haptic output, and/or an output port that is configured to provide an output to further components and/or devices. The input/output unit 907 may further include an input component and/or device, such as a keyboard, and/or a touchscreen display which may be the same touchscreen display used as the output component, and/or a touch panel, and/or a touch pad, and/or a mouse, and/or an input port that is configured to receive an input from further components and/or devices.

The input/output unit 907 may further include a communication circuit, e.g. a radio communication circuit or a wired communication circuit, that is configured to communicate with other components and/or devices. The communication circuit may include a transmitter to transmit communication signals. The communication circuit may include a receiver to receive communication signals.

The computing system 900 may further include an operating system 908. The operating system 908 may be configured to provide an interface between any of the hardware and software resources of the computing system 900. The operating system 908 may be further configured to provide an interface between any of the hardware and software resources and a user via a user interface. The computing system 900 may further include the memory 908 to store any type of data, and the operating system 908 may further be configured to perform memory management for the memory 908.

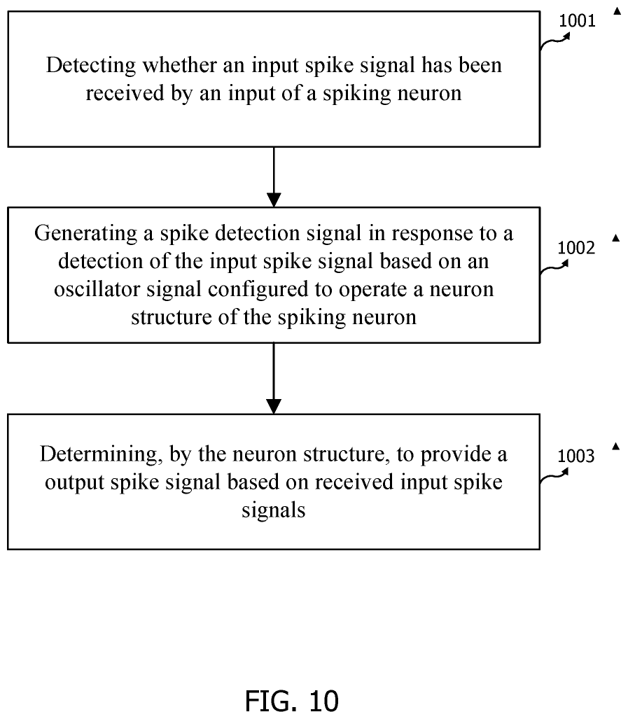

FIG. 10 shows schematically an example of a method. The method may include detecting 1001 whether an input spike signal has been received by an input of a spiking neuron, generating 1002 a spike detection signal in response to a detection of the input spike signal based on an oscillator signal configured to operate a neuron structure of the spiking neuron, determining 1003, by the neuron structure, to provide an output spike signal based on received input spike signals.

The following examples pertain to further aspects of this disclosure.

In example 1, the subject matter includes a spiking neuron including a triggerable and frequency-controllable oscillator to generate an oscillator signal, a spike signal detector coupled to a plurality of inputs, wherein the spike detector is configured to generate spike detection signals in response to detection of input spike signals, wherein the spike detection signals are generated based on the oscillator signal, and a neuron structure configured to provide an output spike signal based on the spike detection signals and the oscillator signal.

In example 2, the subject matter of example 1, can optionally include that the spike signal detector is further configured to generate the spike detection signals in response to the oscillator signal. In example 3, the subject matter of example 1 or example 2, can optionally include that the generated spike detection signals are in synchronization with the oscillator signal. In example 4, the subject matter of any one of examples 1 to 3, can optionally include that the spike detection signals include pulse signals, and can optionally include that optionally the pulse signals have a duration of a period of the oscillator signal.

In example 5, the subject matter of any one of examples 1 to 4, can optionally include that the spike signal detector includes a plurality of spike capturing elements, and can optionally include that each of the plurality of spike capturing elements are coupled to one of the plurality of inputs respectively. In example 6, the subject matter of example 5, can optionally include that each of the spike capturing elements includes a logic configured to switch a state of operation from a first state to a second state in response to the received input spike signal, and can optionally include that the logic is further configured to generate the spike detection signal while operating in the second state in response to the oscillator signal.

In example 7, the subject matter of any one of examples 5 to 6, can optionally include that the logic includes a first flip-flop logic coupled to the input to switch the state of operation from the first state to the second state based on the received input spike signal, and a second flip-flop logic configured to generate the spike detection signal based on the state of the first flip-flop logic in response to the oscillator signal. In example 8, the subject matter of example 7, can optionally include that the first flip-flop logic includes a clock input coupled to the input, and can optionally include that the first flip-flop logic includes an output coupled to an input of the second flip-flop logic,

In example 9, the subject matter of example 8, can optionally include that the second flip-flop logic includes a clock input configured to receive the oscillator signal. In example 10, the subject matter of example 5 to 9, may further include: a trigger circuit coupled to the plurality of spike capturing elements, and can optionally include that the trigger circuit is configured to provide a trigger signal in response to each spike detection signal received from one of the plurality of spike capturing elements.

In example 11, the subject matter of any one of examples 5 to 10, may further include: a weighing structure coupled to the plurality of inputs, and can optionally include that the weighing structure is configured to selectably weigh each received input spike signal. In example 12, the subject matter of example 11, can optionally include that the weighing structure is configured to apply weights for the spike detection signals. In example 13, the subject matter of example 12, can optionally include that the weighing structure is further configured to receive the spike detection signals from the plurality of spike capturing elements, and can optionally include that the weighing structure is further configured to apply the weight for each of the received spike detection signals.

In example 14, the subject matter of any one of examples 12 or 13, can optionally include that the weighing structure is further configured to determine the weight for each received spike detection signal, can optionally include that the weighing structure is further configured to supply weighed spike detection signals based on the determined weight for each of the spike detection signals. In example 15, the subject matter of any one of examples 11 to 14, can optionally include that the weighing structure is further configured to provide an output based on weighed received input spike signals to the neuron structure, and can optionally include that the neuron structure is further configured to provide the output spike signal based on a plurality of outputs of the weighing structure.

In example 16, the subject matter of any one of examples 11 to 15, can optionally include that the weighing structure includes a plurality of weight releasing elements, and can optionally include that each of the plurality of weight releasing elements is configured to apply a weight for the received input spike signal based on the spike detection signal. In example 17, the subject matter of example 16 can optionally include that each of the weight releasing elements includes a memory configured to store a weight value, can optionally include that each of the weight releasing elements is configured to provide an output indicating the stored weight value in response to the respective spike detection signal.

In example 18, the subject matter of any one of examples 16 or 17, can optionally include that each of the weight releasing elements is further configured to supply a weighed pulse signal based on the determined weight in response to the respective spike detection signal. In example 19, the subject matter of any one of examples 16 to 18, can optionally include that the neuron structure is further configured to determine a value for a predefined metric based on the output of the weighing structure, and can optionally include that the neuron structure is further configured to provide the output spike signal if the value of the predefined metric is above a predefined threshold.

In example 20, the subject matter of example 19, can optionally include that the neuron structure is further configured to adjust the value of the predefined metric based on the output of the weighing structure. In example 21, the subject matter of example 19 or example 20, can optionally include that the value of the predefined metric includes the integration value. In example 22, the subject matter of any one of examples 20 or 21, can optionally include that the triggerable and frequency-controllable oscillator is configured to adjust the oscillator signal in response to the spike detection signal.

In example 23, the subject matter of example 22, can optionally include that the triggerable oscillator includes an input to receive a frequency control signal, can optionally include that the triggerable oscillator is further configured to adjust the frequency of the oscillator signal based on the frequency control signal. In example 24, the subject matter of any one of examples 22 or 23, may further include an oscillator controller coupled to the triggerable oscillator to control the frequency of the oscillator signal.

In example 25, the subject matter of example 24, can optionally include that the oscillator controller is configured to adjust the frequency of the oscillator signal based on the value of the predefined metric. In example 26, the subject matter of any one of examples 21 to 25, can optionally include that the neuron structure includes an integration circuit configured to obtain the integration value based on the spike detection signals. In example 27, the subject matter of any one of examples 21 to 26, can optionally include that the neuron structure includes a leakage circuit configured to obtain a leakage value based on the oscillator signal.

In example 28, the subject matter of example 27, can optionally include that the oscillator controller is further configured to control the frequency of the oscillator signal based on the integration value. In example 29, the subject matter of any one of examples 27 or 28, can optionally include that the oscillator controller is further configured to control the frequency of the oscillator signal based on the leakage value. In example 30, the subject matter of any one of examples 27 to 29, can optionally include that the oscillator controller is further configured to control the frequency of the oscillator signal based on the leakage value and the integration value.

In example 31, the subject matter of any one of examples 27 to 30, can optionally include that the integration circuit is further configured to provide an adjustment to the integration value based on the output of the weighing structure. In example 32, the subject matter of any one of examples 27 to 31, can optionally include that the integration circuit is further configured to provide the adjustment in response to the trigger signal. In example 33, the subject matter of any one of examples 27 to 32, can optionally include that the neuron structure further includes a spike generation circuit configured to generate an output spike signal based on the integration value.

In example 34, the subject matter of example 33, can optionally include that the spike generation circuit includes a determiner configured to compare the integration value with a predefined threshold value. In example 35, the subject matter of any one of examples 33 to 34, can optionally include that the determiner is further configured to reset the integration value and the leakage value based on the integration value and the leakage value. In example 36, the subject matter of any one of examples 33 to 35, can optionally include that the weighing structure is further configured to output determined weights for the inputs which the spike detector has generated the spike detection signal.

In example 37, the subject matter of any one of examples 33 to 36, can optionally include that the weight value outputted by weight releasing elements which have not received a pulse detection signal is zero. In example 38, the subject matter of any one of examples 33 to 37, can optionally include that the integration circuit is further configured to receive the determined weights from the weighing structure, can optionally include that the integration circuit includes an adder configured to sum the determined weights provided by the weighing structure. In example 39, the subject matter of any one of examples 33 to 38, can optionally include that the integration circuit includes a memory configured to store the integration value, can optionally include that the integration circuit is further configured to adjust the integration value by adjusting the integration value based on the sum of the determined weights.

In example 40, the subject matter of any one of examples 33 to 38, can optionally include that the integration circuit includes a first accumulator may include a memory to store the integration value, can optionally include that the first accumulator is configured to accumulate the sum of the determined weights in response to the spike detection signal. In example 41, the subject matter of example 40, can optionally include that the leakage circuit includes a memory to store the leakage value, can optionally include that the leakage circuit is further configured to adjust the leakage value in response to the oscillator signal. In example 42, the subject matter of example 41, can optionally include that the leakage circuit includes a second accumulator to store the leakage value; can optionally include that the second accumulator is further configured to accumulate based on the oscillator signal.

In example 43, A spike capturing circuit may include: an input to receive input spike signals a logic circuit configured to switch a state of operation from a first state to a second state in response to a received input spike signal, can optionally include that the logic is further configured to generate a spike detection signal while operating in the second stage in response to an oscillator signal.

In example 44, the spike capturing circuit of example 43 can optionally include that the logic circuit includes: a first flip-flop logic coupled to the input to switch the state of operation from the first state to the second state in response to the received input spike signal, and a second flip-flop logic configured to generate the spike detection signal in response to the oscillator signal.

In example 45, A method may include: detecting whether an input spike signal has been received by an input of a spiking neuron; generating a spike detection signal in response to a detection of the input spike signal based on an oscillator signal configured to operate a neuron structure of the subject matter; determining, by the neuron structure, to provide a output spike signal based on received input spike signals.

In example 46, the method of example 45, may further include generating the spike detection signals in response to the oscillator signal. In example 47, the method of example 45 or example 46, may further include generating the spike detection signals in synchronization with the oscillator signal. In example 48, the method of any one of examples 45 to 47, can optionally include that the spike detection signals include pulse signals, can optionally include that optionally the pulse signals have a duration of a period of the oscillator signal.

In example 49, the method of any one of examples 45 to 48, may further include switching, by a logic coupled to an input, a state of operation from a first state to a second state in response to the received input spike signal, generating the spike detection signal while operating in the second state in response to the oscillator signal. In example 50, the method of example 49, may further include switching, by a first flip-flop logic coupled to the input, the state of operation from the first state to the second state, generating, by a second flip-flop logic, the spike detection signal in response to the oscillator signal.

In example 51, the method of example 45 to 50, may further include: providing a trigger signal in response to the spike detection signals. In example 52, the method of any one of examples 45 to 51, may further include: selectably weighing each received input spike signal. In example 53, the method of example 52, may further include applying weights for the spike detection signals. In example 54, the method of example 53, may further include receiving the spike detection signals, applying the weights for each of the received spike detection signals.

In example 55, the method of any one of examples 53 or 54, may further include determining the weight to be applied for each received spike detection signal, supplying a weighed spike detection signal based on the determined weight for each of the spike detection signals. In example 56, the method of any one of examples 53 to 55, may further include providing an output based on weighed received input spike signals to the neuron structure, providing, by the neuron structure, the output spike signal based on a plurality of outputs of the weighing structure. In example 57, the method of any one of examples 53 to 56, may further include applying a weight for the received input spike signal based on the spike detection signal.

In example 58, the method of example 57 providing an output indicating the stored weight value in response to the spike detection signal. In example 59, the method of any one of examples 57 or 58, may further include supplying a weighed pulse signal based on a determined weight in response to the spike detection signal. In example 60, the method of any one of examples 57 to 59, may further include determining a value for a predefined metric based on the output of the weighing structure, providing the output spike signal if the value of the predefined metric is above a predefined threshold. In example 61, the method of example 60, may further include adjusting the value of the predefined metric based on the output of the weighing structure.

In example 62, the method of example 60 or example 61, may further include can optionally include that the value of the predefined metric includes an integration value. In example 63, the method of any one of examples 60 to 62, may further include adjusting the oscillator signal in response to the spike detection signal. In example 64, the method of example 63, may further include adjust the frequency of the oscillator signal based on a frequency control signal.

In example 65, the method of any one of examples 63 or 64, may further include controlling the frequency of the oscillator signal. In example 66, the method of example 65, may further include adjusting the frequency of the oscillator signal based on the value of the predefined metric. In example 67, the method of any one of examples 62 to 66, may further include obtaining the integration value based on the spike detection signals. In example 68, the method of any one of examples 62 to 66, may further include obtaining a leakage value based on the oscillator signal.

In example 69, the method of example 68, may further include controlling the frequency of the oscillator signal based on the integration value. In example 70, the method of any one of examples 68 or 69, may further include controlling the frequency of the oscillator signal based on the leakage value. In example 71, the method of any one of examples 68 to 70, may further include controlling the frequency of the oscillator signal based on the leakage value and the integration value.

In example 72, the method of any one of examples 62 to 71, may further include providing an adjustment to the integration value based on the output of the weighing structure. In example 73, the method of any one of examples 62 to 72, may further include providing an adjustment to the integration value in response to the trigger signal. In example 74, the method of any one of examples 66 to 73, may further include generating the output spike signal based on the integration value.

In example 75, the method of example 74, may further include comparing the integration value with a predefined threshold value. In example 76, the method of any one of examples 74 to 75, may further include resetting the integration value and the leakage value based on the integration value and the leakage value. In example 77, the method of any one of examples 74 to 76, may further include outputting the determined weights for the inputs which the spike detector has generated the spike detection signal. In example 78, the method of any one of examples 74 to 77, may further include can optionally include that the weight value outputted by weight releasing elements which have not received a pulse detection signal is zero.

In example 79, the method of any one of examples 74 to 79, may further include receiving the determined weights from the weighing structure, summing the determined weights provided by the weighing structure. In example 80, the method of example 79, may further include adjusting the integration value based on the sum of the determined weights. In example 81, the method of any one of examples 74 to 80, may further include accumulating, by a first accumulator, the sum of the determined weights in response to the spike detection signals. In example 82, the method of example 81, may further include adjusting the leakage value in response to the oscillator signal. In example 83, the method of example 82, may further include accumulating, by a second accumulator, the leakage value based on the oscillator signal.

In example 84, A spiking neuron may include: a triggerable and frequency-controllable oscillator means for generating an oscillator signal, a spike signal detector means for generating spike detection signals in response to detection of input spike signals, can optionally include that the spike detection signals are generated based on the oscillator signal, a neuron structure means for providing an output spike signal based on the spike detection signals and the oscillator signal. In example 85, a processor may include a plurality of spiking neurons according to any one of the examples 1 to 44, or capable to perform methods with a plurality of spiking neurons according to any one of examples 45 to 82.

The word “exemplary” is used herein to mean “serving as an example, instance, or illustration”. Any aspect or design described herein as “exemplary” is not necessarily to be construed as preferred or advantageous over other aspects or designs.

Throughout the drawings, it should be noted that like reference numbers are used to depict the same or similar elements, features, and structures, unless otherwise noted. It should be noted that certain components may be omitted for the sake of simplicity. It should be noted that nodes (dots) are provided to identify the circuit line intersections in the drawings including electronic circuit diagrams.

The phrase “at least one” and “one or more” may be understood to include a numerical quantity greater than or equal to one (e.g., one, two, three, four, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. For instance, the phrase “a plurality” may be understood to include a numerical quantity greater than or equal to two (e.g., two, three, four, five, [ . . . ], etc.).

As used herein, a signal that is “indicative of” or “indicating” a value or other information may be a digital or analog signal that encodes or otherwise, communicates the value or other information in a manner that can be decoded by and/or cause a responsive action in a component receiving the signal. The signal may be stored or buffered in computer-readable storage medium prior to its receipt by the receiving component and the receiving component may retrieve the signal from the storage medium. Further, a “value” that is “indicative of” some quantity, state, or parameter may be physically embodied as a digital signal, an analog signal, or stored bits that encode or otherwise communicate the value.

As used herein, a signal may be transmitted or conducted through a signal chain in which the signal is processed to change characteristics such as phase, amplitude, frequency, and so on. The signal may be referred to as the same signal even as such characteristics are adapted. In general, so long as a signal continues to encode the same information, the signal may be considered as the same signal. For example, a transmit signal may be considered as referring to the transmit signal in baseband, intermediate, and radio frequencies.

The terms “processor” or “controller” as, for example, used herein may be understood as any kind of technological entity that allows handling of data. The data may be handled according to one or more specific functions executed by the processor or 9. Further, a processor or controller as used herein may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

The terms “one or more processors” is intended to refer to a processor or a controller. The one or more processors may include one processor or a plurality of processors. The terms are simply used as an alternative to the “processor” or “controller”.

As utilized herein, terms “module”, “component,” “system,” “circuit,” “element,” “slice,” “circuit,” and the like are intended to refer to a set of one or more electronic components, a computer-related entity, hardware, software (e.g., in execution), and/or firmware. For example, circuit or a similar term can be a processor, a process running on a processor, a controller, an object, an executable program, a storage device, and/or a computer with a processing device. By way of illustration, an application running on a server and the server can also be circuit. One or more circuits can reside within the same circuit, and circuit can be localized on one computer and/or distributed between two or more computers. A set of elements or a set of other circuits can be described herein, in which the term “set” can be interpreted as “one or more.”

As used herein, “memory” is understood as a computer-readable medium (e.g., a non-transitory computer-readable medium) in which data or information can be stored for retrieval. References to “memory” included herein may thus be understood as referring to volatile or non-volatile memory, including random access memory (RAM), read-only memory (ROM), flash memory, solid-state storage, magnetic tape, hard disk drive, optical drive, 3D Points, among others, or any combination thereof. Registers, shift registers, processor registers, data buffers, among others, are also embraced herein by the term memory. The term “software” refers to any type of executable instruction, including firmware.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art. The term “data item” may include data or a portion of data.

It will be understood that when an element is referred to as being “connected” or “coupled” to another element, it can be physically connected or coupled to the other element such that current and/or electromagnetic radiation (e.g., a signal) can flow along a conductive path formed by the elements. Intervening conductive, inductive, or capacitive elements may be present between the element and the other element when the elements are described as being coupled or connected to one another. Further, when coupled or connected to one another, one element may be capable of inducing a voltage or current flow or propagation of an electro-magnetic wave in the other element without physical contact or intervening components. Further, when a voltage, current, or signal is referred to as being “provided” to an element, the voltage, current, or signal may be conducted to the element by way of a physical connection or by way of capacitive, electro-magnetic, or inductive coupling that does not involve a physical connection.

Unless explicitly specified, the term “transmit” encompasses both direct (point-to-point) and indirect transmission (via one or more intermediary points). Similarly, the term “receive” encompasses both direct and indirect reception. Furthermore, the terms “transmit,” “receive,” “communicate,” and other similar terms encompass both physical transmission (e.g., the transmission of radio signals) and logical transmission (e.g., the transmission of digital data over a logical software-level connection). For example, a processor or controller may transmit or receive data over a software-level connection with another processor or controller in the form of radio signals, where the physical transmission and reception is handled by radio-layer components such as RF transceivers and antennas, and the logical transmission and reception over the software-level connection is performed by the processors or controllers. The term “communicate” encompasses one or both of transmitting and receiving, i.e., unidirectional or bidirectional communication in one or both of the incoming and outgoing directions. The term “calculate” encompasses both ‘direct’ calculations via a mathematical expression/formula/relationship and ‘indirect’ calculations via lookup or hash tables and other array indexing or searching operations.

While the above descriptions and connected figures may depict electronic device components as separate elements, skilled persons will appreciate the various possibilities to combine or integrate discrete elements into a single element. Such may include combining two or more circuits to form a single circuit, mounting two or more circuits onto a common chip or chassis to form an integrated element, executing discrete software components on a common processor core, etc. Conversely, skilled persons will recognize the possibility to separate a single element into two or more discrete elements, such as splitting a single circuit into two or more separate circuits, separating a chip or chassis into discrete elements originally provided thereon, separating a software component into two or more sections and executing each on a separate processor core, etc.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

What is claimed is:

1- A spiking neuron, comprising:
a triggerable and frequency-controllable oscillator to generate an oscillator signal;
a spike signal detector coupled to a plurality of inputs, the spike detector configured to generate spike detection signals in response to detection of input spike signals, wherein the spike detection signals are generated based on the oscillator signal;
a neuron structure configured to provide an output spike signal based on the spike detection signals and the oscillator signal.

2- The spiking neuron of claim 1,
wherein the spike signal detector is further configured to generate the spike detection signals in response to the oscillator signal.

3- The spiking neuron of claim 1,
wherein the spike detection signals are in synchronization with the oscillator signal.

4- The spiking neuron of claim 1,
wherein the spike detection signals comprise pulse signals, wherein optionally the pulse signals have a duration of a period of the oscillator signal.

5- The spiking neuron of claim 1,
wherein the spike signal detector comprises a plurality of spike capturing elements, and
wherein each of the plurality of spike capturing elements is coupled to one of the plurality of inputs respectively.

6- The spiking neuron of claim 5,
wherein each of the plurality of spike capturing elements comprises a logic configured to switch a state of operation from a first state to a second state in response to the received input spike signal, and
wherein the logic is further configured to generate the spike detection signal while operating in the second state in response to the oscillator signal.

7- The spiking neuron of claim 6,
wherein the logic comprises a first flip-flop logic coupled to one of the plurality of inputs to switch the state of operation from the first state to the second state, and a second flip-flop logic configured to generate the spike detection signal in response to the oscillator signal,
wherein the first flip-flop logic comprises a clock input coupled to the one of the plurality of inputs,
wherein the first flip-flop logic comprises an output coupled to an input of the second flip-flop logic, and
wherein the second flip-flop logic comprises a clock input configured to receive the oscillator signal.

8- The spiking neuron of claim 1, further comprising:
a weighing structure coupled to the plurality of inputs, wherein the weighing structure is configured to selectably weigh each of the received input spike signals.

9- The spiking neuron of claim 8,
wherein the weighing structure is further configured to receive the spike detection signals from a plurality of spike capturing elements, and
wherein the weighing structure is further configured to apply the weight for each of the received spike detection signals.

10- The spiking neuron of claim 9,
wherein the weighing structure comprises a plurality of weight releasing elements,
wherein each of the plurality of weight releasing elements are coupled to one of the plurality of spike capturing elements, and
wherein each of the plurality of weight releasing elements is configured to apply a weight for the received input spike signal based on the spike detection signal received from the respective one of the plurality of spike capturing elements.

11- The spiking neuron of claim 10,
wherein each of the weight releasing elements comprises a memory configured to store a weight value, and
wherein each of the weight releasing elements is configured to provide an output indicating the stored weight value in response to the spike detection signal received from the respective one of the plurality of spike capturing elements.

12- The spiking neuron of claim 11,
wherein the neuron structure is further configured to adjust a value for a predefined metric based on the output of the weighing structure,
wherein the neuron structure is further configured to provide the output spike signal if the value of the predefined metric is above a predefined threshold, and
wherein the value of the predefined metric comprises the integration value.

13- The spiking neuron of claim 12, further comprising
an oscillator controller coupled to the triggerable and frequency-controllable oscillator to control the frequency of the oscillator signal, and
wherein the oscillator controller is configured to adjust the frequency of the oscillator signal based on the value of the predefined metric.

14- The spiking neuron of claim 13,
wherein the neuron structure comprises an integration circuit configured to obtain the integration value based on the spike detection signals.

15- The spiking neuron of claim 14,
wherein the integration circuit is further configured to provide an adjustment to the integration value in response to the spike detection signals.

16- The spiking neuron of claim 14,
wherein the neuron structure comprises a leakage circuit configured to obtain a leakage value based on the oscillator signal.

17- The spiking neuron of claim 16,
wherein the oscillator controller is further configured to control the frequency of the oscillator signal based on at least one of the integration value and the leakage value.

18- The spiking neuron of claim 12,
wherein the neuron structure further comprises a spike generation circuit configured to generate an output spike signal based on the integration value.

19- The spiking neuron of claim 16,
wherein the spike generation circuit comprises a determiner configured to compare the integration value with a predefined threshold value, and
wherein the determiner is further configured to reset the integration value and the leakage value based on the integration value and the leakage value.

20- A spike capturing circuit comprising:
an input to receive input spike signals
a logic circuit configured to switch a state of operation from a first state to a second state in response to a received input spike signal, wherein the logic is further configured to generate a spike detection signal while operating in the second state in response to an oscillator signal.

21- The spike capturing circuit of claim 20,
wherein the logic circuit comprises:
a first flip-flop logic coupled to the input to switch the state of operation from the first state to the second state in response to the received input spike signal, and
a second flip-flop logic configured to generate the spike detection signal in response to the oscillator signal.

22- A method comprising:
detecting whether an input spike signal has been received by an input of a spiking neuron;
generating spike detection signals in response to detection of the input spike signals based on an oscillator signal configured to operate a neuron structure of the spiking neuron;
determining, by the neuron structure, to provide an output spike signal based on the spike detection signals.

23- The method of claim 22, further comprising:
generating the spike detection signals in response to the oscillator signal,
wherein the generated spike detection signals are in synchronization with the oscillator signal.

24- A spiking neuron comprising:
a triggerable and frequency-controllable oscillator means for generating an oscillator signal,
a spike signal detector means for generating spike detection signals in response to detection of input spike signals, wherein the spike detection signals are generated based on the oscillator signal,
a neuron structure means for providing an output spike signal based on the spike detection signals and the oscillator signal.

25- The spiking neuron of claim 24, further comprising:
wherein the spike signal detector means is further configured to generate the spike detection signals in response to the oscillator signal.
